(19) United States
(12) Patent Application Publication
(10) Pub. No.: US 2026/0212913 A1
(43) Pub. Date: Jul. 23, 2026

(54) MEMORY DEVICE AND METHOD OF OPERATING THE SAME

(71) Applicant: SAMSUNG ELECTRONICS CO., LTD., Suwon-si (KR)

(72) Inventors: Kangsub JEONG, Suwon-si (KR); Kyu-Chang KANG, Suwon-si (KR)

(73) Assignee: SAMSUNG ELECTRONICS CO., LTD., Suwon-si (KR)

(21) Appl. No.: 19/380,296

(22) Filed: Nov. 5, 2025

(30) Foreign Application Priority Data
Jan. 22, 2025 (KR) 10-2025-0009723

(51) Int. Cl. G11C 11/4091; G11C 11/4094

(52) U.S. Cl. CPC G11C 11/4091; G11C 11/4094

(57) ABSTRACT

Provided are a memory device and a method of operating the same. The memory device includes: a first sub-memory array, a second sub-memory array and a third sub-memory array arranged sequentially along a first direction; a first bit line selection circuit connected to a first bit line in the first sub-memory array and a second bit line in the second sub-memory array, wherein the first bit line and the second bit line extend along the first direction; and a first bit line sense amplifier connected to an output terminal of the first bit line selection circuit and a third bit line in the third sub-memory array and extending along the first direction.

### CROSS-REFERENCE TO RELATED APPLICATION

This application claims priority to Korean Patent Application No. 10-2025-0009723 filed with the Korean Patent Office on January 22, 2025, the disclosure of which is incorporated by reference herein in its entirety.

### BACKGROUND

The present disclosure relates to a memory device and a method of operating the memory device.

Semiconductor memory devices may be used to store data. For example, Random Access Memory (RAM) is a volatile memory device which may be used as a main memory device of computers. Dynamic Random Access Memory (DRAM) is a type of RAM that contains volatile memory cells. To efficiently detect data stored in a memory cell in a DRAM, a bit line and a complementary bit line are precharged, and a charge sharing operation is performed to create a difference between the voltage level of the bit line and the voltage level of the complementary bit line. The bit line sense amplifier may detect data stored in memory cells by amplifying the difference in voltage levels, i.e., the voltage difference between the bit line and the complementary bit line.

Recently, with the development of the electronics industry, the demand for high functionality and miniaturization of electronic components has increased. Accordingly, the area of the memory cell area and the peripheral circuits arranged adjacent to the memory cell area to operate the memory cells have been reduced, thereby improving the integration of memory devices. As one method for improving integration, a structure in which peripheral circuits are embedded under the memory cell area (Cell Over Peri, COP) or a structure in which memory cells are embedded under the peripheral circuits (Peri Over Cell, POC) have been proposed.

### SUMMARY

One or more embodiments provide a three-dimensionally structured memory device with improved area efficiency.

According to an aspect of an embodiment, a memory device includes: a first sub-memory array, a second sub-memory array and a third sub-memory array arranged sequentially along a first direction; a first bit line selection circuit connected to a first bit line in the first sub-memory array and a second bit line in the second sub-memory array, wherein the first bit line and the second bit line extend along the first direction; and a first bit line sense amplifier connected to an output terminal of the first bit line selection circuit and a third bit line in the third sub-memory array and extending along the first direction.

According to another aspect of an embodiment, a memory device includes: a memory cell area including a first sub-memory array, a second sub-memory array and a third sub-memory array arranged sequentially along a first direction; and a first local sense amplifier circuit between the first sub-memory array and the second sub-memory array. The first local sense amplifier circuit at least partially overlaps the first sub-memory array and the second sub-memory array along a third direction. The first local sense amplifier circuit is connected to a first bit line in the first sub-memory array that extends along the first direction, a second bit line in the second sub-memory array that extends along the first direction, and a third bit line in the third sub-memory array that extends along the first direction.

According to another aspect of an embodiment, a method of operating a memory device includes: selecting a sensing bit line pair from among a first bit line, a second bit line and a third bit line respectively arranged in a first sub-memory array, a second sub-memory array and a third sub-memory array that are sequentially arranged along a first direction; activating a word line in any one of the first sub-memory array to the third sub-memory array based on a row address, to perform a charge sharing operation between the sensing bit line pair and a memory cell connected to the word line; detecting data of the sensing bit line pair based on the charge sharing operation; and transmitting data of the sensing bit line pair to a local input/output line pair based on a column selection signal.

### BRIEF DESCRIPTION OF DRAWINGS

The above and other aspects and features will be more apparent from the following description of embodiments with reference to the attached drawings.

FIG. 1 is a block diagram illustrating a memory system according to some embodiments.

FIG. 2 is a block diagram illustrating a memory device according to some embodiments.

FIG. 3 is a perspective view showing a memory device according to some embodiments.

FIG. 4 is a plan view illustrating a bank array according to some embodiments.

FIG. 5 is a plan view for explaining the low block group of FIG. 4 according to some embodiments.

FIG. 6 is an enlarged circuit diagram of area A in FIG. 5 according to some embodiments.

FIG. 7 is a block diagram illustrating a local sense amplifier circuit according to some embodiments.

FIG. 8 is a block diagram illustrating a bit line sense amplifier according to some embodiments.

FIG. 9 is a cross-sectional view taken along lines C to C’ of an example memory device of FIG. 4 according to some embodiments.

FIG. 10 is an enlarged view of area AA in FIG. 9 according to some embodiments.

FIG. 11 is a flowchart illustrating a method of operating a memory device according to some embodiments.

FIGS. 12 to 14 are drawings for explaining a method of operating a memory device according to some embodiments.

FIGS. 15 and 16 are drawings illustrating memory devices according to some embodiments.

FIGS. 17 to 19 are drawings illustrating memory devices according to some embodiments.

FIG. 20 is a cross-sectional view taken along line C-C’ of an example of the memory device of FIG. 3 according to some embodiments.

FIG. 21 is a block diagram illustrating a computer device according to some embodiments.

### DETAILED DESCRIPTION

Hereinafter, embodiments are described in detail with reference to the attached drawings. The present disclosure may be embodied in many different forms and is not limited to the embodiments described herein. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure.

In order to clearly explain the present disclosure, parts irrelevant to the description are omitted, and identical or similar reference numerals are given to identical or similar components throughout the specification.

Additionally, throughout the specification, whenever a part is said to “include” a component, this does not mean that it excludes other components, but rather that it may include other components, unless otherwise specifically stated.

Additionally, a specific number set forth in a claim, even if explicitly recited in the claim, should not be construed as meaning that there is limitation to the specific number in the claim where such recitation does not exist. For example, the terms "1st" or "first" and "2nd" or "second" may use corresponding components regardless of importance or order and are used to distinguish a component from another component without limiting the components.

Moreover, expressions such as "at least one of" when preceding a list of elements, modify the entire list of elements and do not modify the individual elements of the list. For example, the expression, "at least one of a, b, and c," should be understood as including only a, only b, only c, both a and b, both a and c, both b and c, or all of a, b, and c.

The terms “module,” “unit,” “part,” and the like, as used in this document, are terms intended to refer to a component that performs at least one function or operation, and such a component may be implemented as hardware or software, or as a combination of hardware and software.

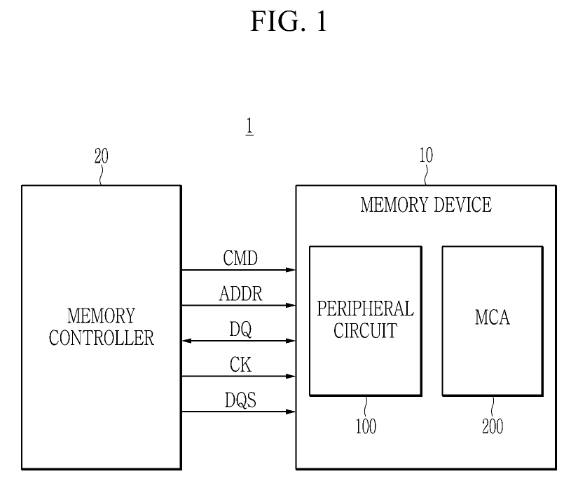

FIG. 1 is a block diagram illustrating a memory system according to some embodiments.

Referring to FIG. 1, a memory system 1 may include a memory device 10 and a memory controller 20.

The memory controller 20 controls the overall operation of the memory system 1 and controls the overall data exchange between the external host and the memory device 10. For example, the memory controller 20 may control the memory device 10 to write data or read data according to request of the host.

Additionally, the memory controller 20 may control the operation of the memory device 10 by applying operation commands for controlling the memory device 10. According to an embodiment, the memory device 10 may be a dynamic random access memoroy (DRAM), a double data rate 5 (DDR5) synchronous DRAM (SDRAM), or a double data rate 6 (DDR6) SDRAM having volatile memory cells.

The memory controller 20 may include a processor that controls the overall operation of the memory controller 20, and the memory controller 20 may control the memory device 10 based on the operation of the processor. The memory controller 20 may transmit a clock signal (CK, or command clock signal) and a command CMD and an address ADDR to the memory device 10. When the memory controller 20 transmits a data signal DQ to the memory device 10 or receives a data signal DQ from the memory device 10, the memory controller 20 may exchange a data strobe signal DQS with the memory device 10. An address ADDR may be accompanied by a command CMD, and in the present disclosure, the address ADDR may be referred to as an access address.

A memory device 10 may include peripheral circuits 100 and a memory cell array 200 that stores data. The peripheral circuit 100 may control the operation of the memory cell array 200. The memory cell array 200 may include a plurality of bank arrays, and each of the bank arrays may include a plurality of sub-memory arrays including a plurality of volatile memory cells. Additionally, each bank array is divided into a plurality of row blocks by row block identification bits, which are part of the row address bits, and each of the row blocks may include a plurality of sub-memory arrays arranged in one direction.

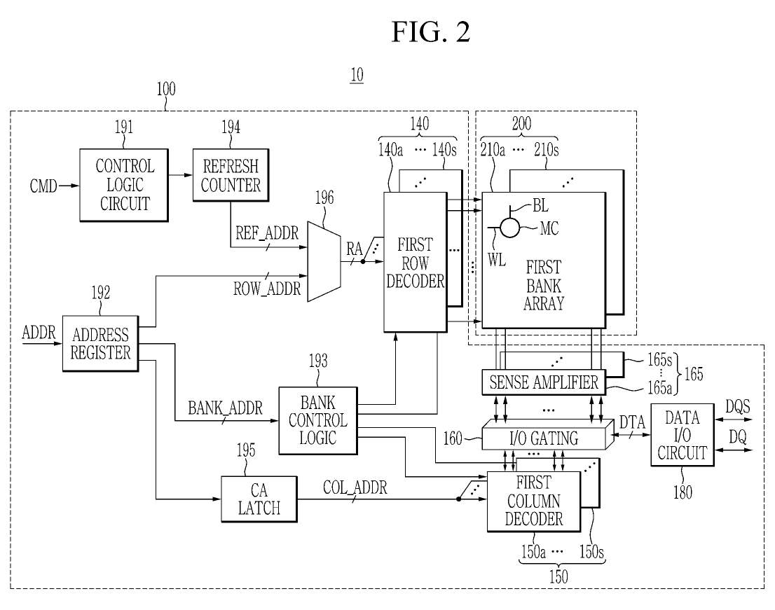

FIG. 2 is a block diagram illustrating a memory device according to some embodiments.

Referring to FIGS. 1 and 2, a memory device 10 may include a peripheral circuit 100 and a memory cell array 200. The peripheral circuit 100 may include a control logic circuit 191, an address register 192, a bank control logic 193, a refresh counter 194, a column address latch 195, a row address multiplexer 196, a row decoder 140, a column decoder 150, a sense amplifier unit 165, an input/output gating circuit 160, and a data input/output buffer 180.

The memory cell array 200 may include first to sixteenth bank arrays 210a to 210s. The row decoder 140 may include first to sixteenth row decoders 140a to 140s connected to the first to sixteenth bank arrays 210a to 210s, respectively. The column decoder 150 may include first to sixteenth column decoders 150a to 150s connected to the first to sixteenth bank arrays 210a to 210s, respectively. The sense amplifier unit 165 may include first to sixteenth sense amplifiers 165a to 165s connected to the first to sixteenth bank arrays 210a to 210s, respectively.

Each of the first to sixteenth bank arrays 210a to 210s, each of the first to sixteenth sense amplifiers 165a to 165s, each of the first to sixteenth column decoders 150a to 150s, and each of the first to sixteenth row decoders 140a to 140s, which are connected to one another, may operate as the first to sixteenth banks. Each of the first to sixteenth bank arrays 210a to 210s may include a plurality of word lines WL, a plurality of bit lines BL, and a plurality of memory cells MC arranged at points where the word lines WL and the bit lines BL intersect. Although the memory device 10 in FIG. 2 is illustrated as including 16 banks, the technical idea of the present disclosure is not limited to the example of the number of banks.

Each of the first to sixteenth bank arrays 210a to 210s may include a plurality of memory cells MC, which are a plurality of volatile memory cells that store data. Additionally, each of the first to sixteenth bank arrays210a to 210s includes a plurality of sub-memory arrays, and the plurality of sub-memory arrays may be divided into a plurality of row blocks by row block identification bits, which are some bits of a row address. The above row block may include a plurality of sub-memory arrays arranged in one direction.

In some embodiments, three sub-memory arrays arranged sequentially and having different row blocks may operate together as a group. For example, when a word line of one sub-memory array is activated, any one of the bit lines of another sub-memory array of the same group may be selected as a complementary sensing bit line. Therefore, bit lines of different sub-memory arrays that are in the same group but are not adjacent may operate as a single sensing bit line pair.

The control logic circuit 191 may control the operation of the memory device 10. For example, the control logic circuit 191 may generate control signals to cause the memory device 10 to perform a write operation or a read operation. The control logic circuit 191 may include a command decoder for decoding a received command CMD and a mode register for setting the operating mode of the memory device 10. For example, the command decoder may decode a chip select signal and a command/address signal, etc., to generate the control signals corresponding to the command CMD. In particular, the above command decoder may decode a command CMD and generate a control signal for controlling an input/output gating circuit 160, etc.

The address register 192 may receive an address ADDR including a bank address BANK_ADDR, a row address ROW_ADDR, and a column address COL_ADDR from the memory controller 20. The address register 192 may provide a received bank address BANK_ADDR to the bank control logic 193, a received row address ROW_ADDR to the row address multiplexer 196, and a received column address COL_ADDR to the column address latch 195.

The bank control logic 193 may generate a bank control signal in response to a bank address BANK_ADDR. In response to the above bank control signal, a row decoder corresponding to the bank address BANK_ADDR among the first to sixteenth row decoders 140a to 140s may be activated, and a column decoder corresponding to the bank address BANK_ADDR among the first to sixteenth column decoders 150a to 150s may be activated.

The row address multiplexer 196 may receive a row address ROW_ADDR from the address register 192 and a refresh row address REF_ADDR from the refresh counter 194. The row address multiplexer 196 may selectively output the row address ROW_ADDR or the refresh row address REF_ADDR as the row address RA. The row address RA output from the row address multiplexer 196 may be applied to each of the first to sixteenth row decoders 140a to 140s.

Among the first to sixteenth row decoders 140a to 140s, a row decoder activated by the bank control logic 193 may decode a row address RA output from a row address multiplexer 196 and activate a word line corresponding to the row address RA.

Each of the first to sixteenth row decoders 140a to 140s may be electrically connected to a plurality of sub word line drivers or may include a plurality of sub word line drivers. For example, a row decoder may activate a sub word line driver corresponding to a row address RA to apply a word line driving voltage to a word line corresponding to the row address.

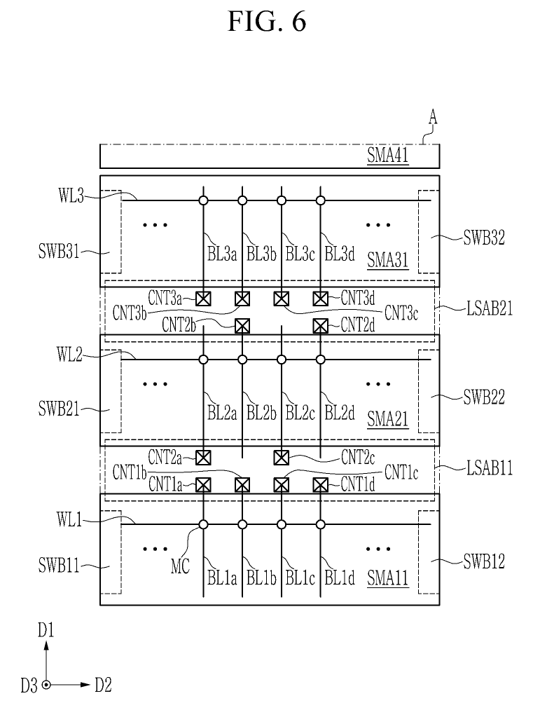

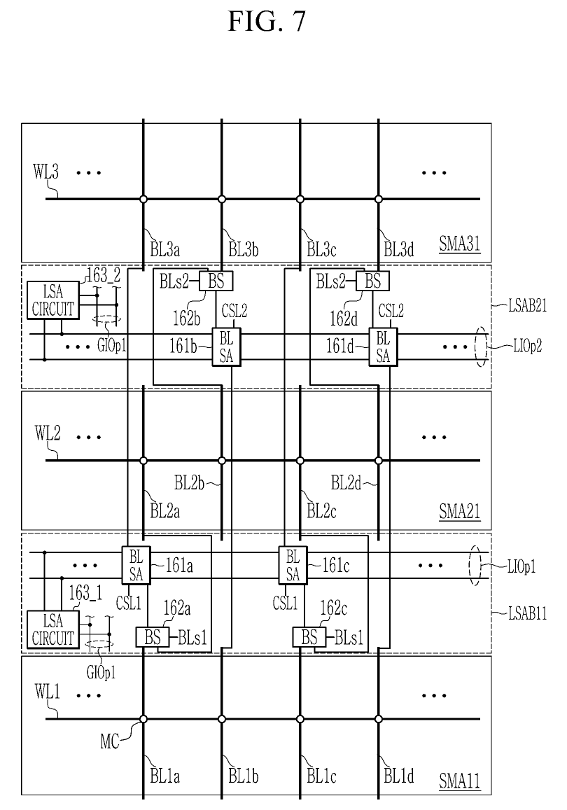

Each of the first to sixteenth row decoders 140a to 140s may provide a bit line selection signal to a local sense amplifier circuit arranged adjacent to a plurality of sub-memory arrays based on a row address RA. The above local sense amplifier circuit may select a sensing bit line pair for an activated word line based on a bit line select signal. The above local sense amplifier circuit and the bit line selection signal are described later in the description of FIGS. 6 and 7.

The column address latch 195 may receive a column address COL_ADDR from the address register 192 and temporarily store the received column address COL_ADDR. Additionally, the column address latch 195 may incrementally increase the received column address COL_ADDR in burst mode. The column address latch 195 may apply a temporarily stored or gradually increased column address COL_ADDR to the first to sixteenth column decoders 150a to 150s, respectively.

Among the first to sixteenth column decoders 150a to 150s, a column decoder activated by the bank control logic 230 may activate a sense amplifier corresponding to the bank address BANK_ADDR and the column address COL_ADDR through a corresponding input/output gating circuit 160. For example, a column decoder activated by the bank control logic 230 may activate a sensing bit line pair and a bit line sense amplifier corresponding to a column address COL_ADDR through an input/output gating circuit 160.

The input/output gating circuit 160 may include circuits for gating input/output data, input data mask logic, a read data latch for storing data DTA output from the first to sixteenth bank arrays 210a to 210s, and write drivers for writing data to the first to sixteenth bank arrays 210a to 210s.

Data DTA read from one of the first to sixteenth bank arrays 210a to 210s may be detected by a sense amplifier corresponding to the one bank array and stored in the read data latch. Data DTA stored in the above read data latch is provided to a data input/output buffer 180, and the data input/output buffer 180 may convert the data DTA into a data signal DQ based on the data DTA and provide the data signal DQ to the memory controller 20 together with a data strobe signal DQS.

A data signal DQ to be written to one of the first to sixteenth bank arrays 210a to 210s is received by a data input/output buffer 180 together with a data strobe signal DQS. The data input/output buffer 180 may convert a data signal DQ into data DTA and provide it to the input/output gating circuit 160. The input/output gating circuit 160 may write data DTA to a target page of one bank array through the write drivers.

In some embodiments, the memory device 10 may further include an ECC engine. The ECC engine may receive data DTA from a data input/output buffer 180 in a write operation, perform ECC encoding, generate a codeword including data DTA and parity data (or parity bit) for the data DTA, and provide the codeword to an input/output gating circuit 160. The ECC engine may receive a codeword provided from the input/output gating circuit 160 in a read operation, perform ECC decoding, and provide data DTA to the data input/output buffer 180.

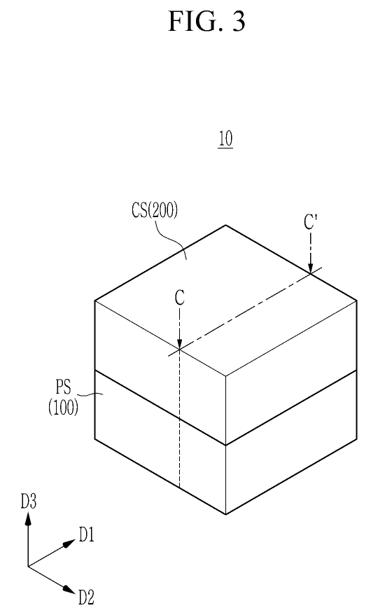

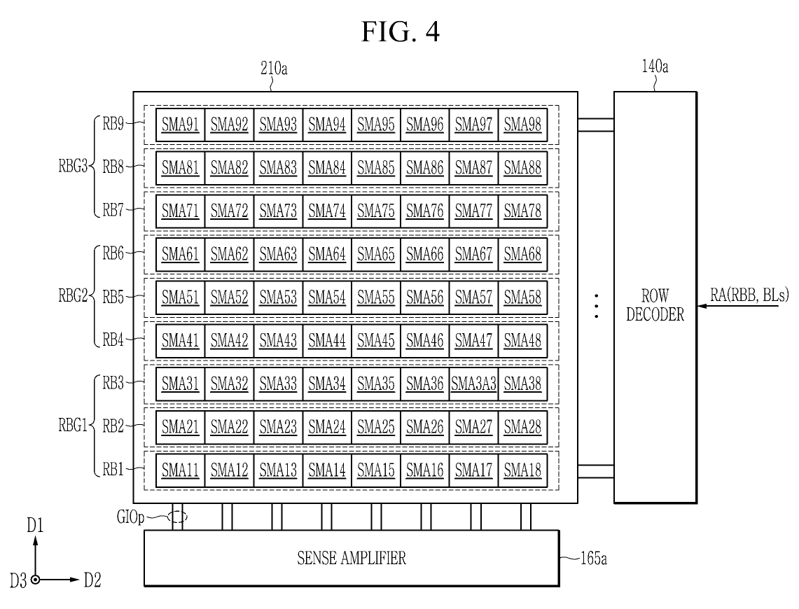

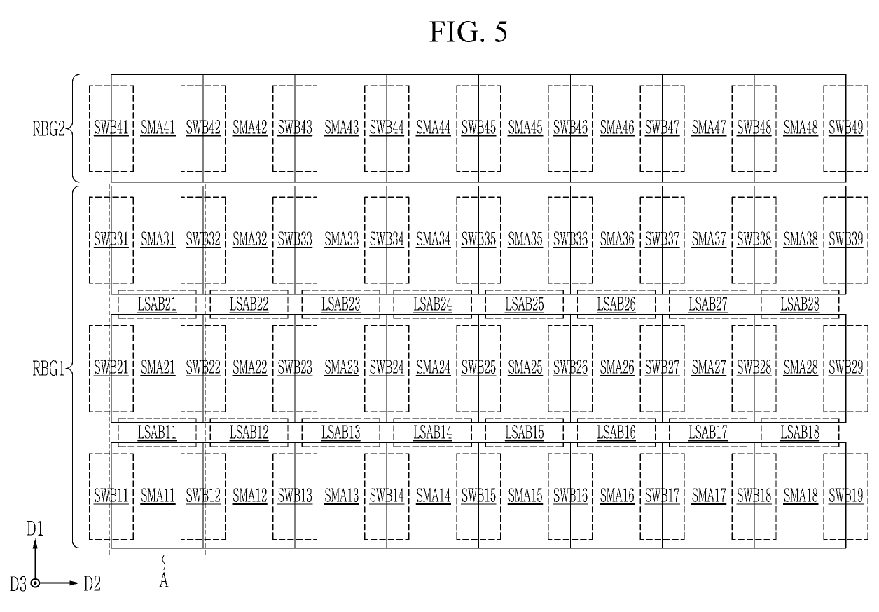

FIG. 3 is a perspective view showing a memory device according to some embodiments. FIG. 4 is a plan view illustrating a bank array according to some embodiments. FIG. 5 is a plan view for explaining the low block group of FIG. 4.

Referring to FIGS. 2 to 5, according to embodiments, a memory device 10 may include a peripheral circuit area PS and a memory cell area CS. The memory device 10 may have a Cell Over Peri (COP) structure or a Peri Over Cell (POC) structure, and the peripheral circuit area PS and the memory cell area CS may be three-dimensionally stacked in a third direction D3. The third direction D3 may be perpendicular to the substrate of the peripheral circuit area PS and the memory cell area CS. The memory cell area CS may be a region where a memory cell array 200 is provided, and the peripheral circuit area PS may be a region where a peripheral circuit 100 that controls the operation of the memory cell array 200 is provided.

At least a portion of the peripheral circuit area PS may overlap the memory cell area CS along the third direction D3. According to an embodiment, the peripheral circuit area PS may include a portion of an external pad or wiring body disposed on the memory cell area CS.

The memory cell area CS may include a memory cell array 200, and the memory cell array 200 may include first to sixteenth bank arrays 210a to 210s. The first to sixteenth bank arrays 210a to 210s may be arranged so as to not overlap along the third direction D3. According to an embodiment, the first to sixteenth bank arrays 210a to 210s may be arranged on the same substrate.

Below, the components and arrangement of the components within the memory device 10 based on the first bank array 210a are described. It will be appreciated that the description of the first bank array 210a may be applied in the same or similar manner to the first to sixteenth bank arrays 210a to 210s.

The first bank array 210a may include a plurality of sub memory arrays SMA11 to SMA98. A plurality of sub memory arrays SMA11 to SMA98 may be connected to the first row decoder 140a and the first sense amplifier 165a.

The first sense amplifier 165a may be connected to the plurality of sub memory arrays SMA11 to SMA98 through global input/output line pairs GIOp. According to an embodiment, one global input/output line of a global input/output line pair GIOp may be connected to local sense amplifier circuits arranged in a first direction D1. For example, some of the local sense amplifier circuits arranged in the first direction D1 among the local sense amplifier circuits connected to the 1-1 to 9-1 sub-memory arrays SMA11 to SMA91 may be connected to the first sense amplifier 165a through a global input/output line pair GIOp.

The first row decoder 140a may be electrically connected to a plurality of sub word line drivers, and the first row decoder 140a may activate a sub word line driver corresponding to a row address RA among the plurality of sub word line drivers. An activated sub word line driver may provide driving voltage to the word line corresponding to the row address RA.

The first row decoder 140a may provide a bit line selection signal BLs corresponding to a row address RA to a local sense amplifier circuit including a local sense amplifier circuit, thereby selecting a sensing bit line pair connected to the local sense amplifier circuit. The local sense amplifier circuit may select a sensing bit line pair for an activated word line based on bit line select signals BLs.

In FIG. 4, the first sense amplifier 165a and the first row decoder 140a are depicted as being arranged so as not to overlap the first bank array 210a in a planar manner. However, the arrangement of the first sense amplifier 165a and the first row decoder 140a depicted in FIG. 4 is for explaining the connection relationship with the components. According to an embodiment, at least a portion of the first sense amplifier 165a and at least a portion of the first row decoder 140a may overlap the first bank array 210a in the third direction D3.

A plurality of sub-memory arrays SMA11 to SMA98 may be classified into first to ninth row blocks RB1 to RB9 that extend in the second direction D2. The first to ninth row blocks RB1 to RB9 may be arranged in the first direction D1 by row block identification bits RBB, which are some bits of the row address RA. For example, by means of a plurality of upper bits of a row address RA, which are row block identification bits RBB, a plurality of sub memory arrays SMA11 to SMA98 may be distinguished into first to ninth row blocks RB1 to RB9 arranged in a first direction D1.

Although the first bank array 210a of FIG. 5 includes a plurality of sub-memory arrays arranged in nine row blocks and eight column blocks, embodiments are not limited thereto, and the number of row blocks and column blocks included in the bank array may vary. In the present disclosure, a ‘row block’ means a set of a plurality of sub-memory arrays arranged in a second direction D2 in which a word line extends, and a ‘column block’ means a set of a plurality of sub-memory arrays arranged in a first direction D1 in which a bit line extends.

According to an embodiment, the first bank array 210a may include a plurality of three row blocks, and three row blocks arranged sequentially in the first direction D1 may be distinguished as the same row block group by a portion of the row block identification bit RBB. The first to third row blocks RB1 to RB3 arranged sequentially in the first direction D1 may be classified into a first row block group RBG1. Similarly, the fourth to sixth row blocks RB4 to RB6 arranged sequentially in the first direction D1 may be classified into a second row block group RBG2, and the seventh to ninth row blocks RB7 to RB9 arranged sequentially in the first direction D1 may be classified into a third row block group RBG3.

The three sub-memory arrays included in each of the first to third row blocks RB1 to RB3 may operate as a set. For example, the 1-1 sub-memory array SMA11 of the 1st row block RB1, the 2-1 sub-memory array SMA21 of the second row block RB2, and the 3-1 sub-memory array SMA31 of the third row block RB3 may operate as one set. Similarly, the three sub memory arrays included in each of the fourth to sixth row blocks RB4 to RB6 may operate as one set, and the three sub memory arrays included in each of the seventh to ninth row blocks RB7 to RB9 may operate as one set.

Taking FIG. 4 as an example, the 1-1 to 3-1 sub-memory arrays SMA11 to SMA31 arranged in the same column block in the same first row block group RBG1 may operate as one set. When the word line of the 1-1 sub-memory array SMA11 is activated, any one of the bit lines of the 2-1 to 3-1 sub-memory arrays SMA21 to SMA31 may be selected as a complementary sensing bit line. According to an embodiment, a bit line of a 1-1 sub-memory array SMA11 and a bit line of a 1_3 sub-memory array SMA13, which are arranged non-adjacently but in the same first row block group RBG1, may operate as one sensing bit line pair.

According to an embodiment, the first row block RB1 may include the 1-1 to 1-8 sub-memory arrays SMA11 to SMA18 that are classified as the same row block by a row block identification bit RBB. The 1-1 to 1-8 sub-memory arrays SMA11 to SMA18 may be arranged in the second direction D2. The second row block RB2 may include 2-1 to 2-8 sub-memory arrays SMA21 to SMA28 that are classified as the same row block by a row block identification bit RBB. The 2-1 to 2-8 sub-memory arrays SMA21 to SMA28 may be arranged in the second direction D2. The third row block RB3 may include 3-1 to 3-8 sub-memory arrays SMA31 to SMA38 that are classified as the same row block by a row block identification bit RBB. The 3-1 to 3-8 sub-memory arrays SMA31 to SMA38 may be arranged in the second direction D2.

Below, the components and arrangement of the components within the first bank array 210a based on the first low block group RBG1 are described. The description of the first low block group RBG1 may be applied in the same or similar manner to the first to third low block groups RBG1 to RBG3.

Each of the 1-1 to 1-8 sub-memory arrays SMA11 to SMA18 may include a plurality of word lines extending in the second direction D2, a plurality of bit lines extending in the first direction D1, and memory cells connected to the plurality of word lines and the plurality of bit lines. Each of the 2-1 to 2-8 sub-memory arrays SMA21 to SMA28 may include a plurality of word lines extending in the second direction D2, a plurality of bit lines extending in the first direction D1, and memory cells connected to the plurality of word lines and the plurality of bit lines. Each of the 3-1 to 3-8 sub-memory arrays SMA31 to SMA38 may include a plurality of word lines extending in the second direction D2, a plurality of bit lines extending in the first direction D1, and memory cells connected to the plurality of word lines and the plurality of bit lines.

According to an embodiment, each of the 1-1 to 1-8 sub-memory arrays SMA11 to SMA18 may include a first predetermined number of word lines and a second predetermined number of bit lines intersecting one word line. According to an embodiment, each of the 2-1 to 2-8 sub-memory arrays SMA21 to SMA28 may include a first predetermined number of word lines and a second predetermined number of bit lines intersecting one word line. According to an embodiment, each of the 3-1 to 3-8 sub-memory arrays SMA31 to SMA38 may include a first predetermined number of word lines and a second predetermined number of bit lines intersecting one word line.

According to an embodiment, the bit lines of the 1-1 sub-memory array SMA11, the bit lines of the 2-1 sub-memory array SMA21, and the bit lines of the 3-1 sub-memory array SMA31 may correspond to each other, and the three bit lines corresponding to each other may operate as a set. In this regard, when any one word line of the 1-1 sub-memory array SMA11, the 2nd sub-memory array SMA21, and the 3-1 sub-memory array SMA31 is activated, two of the three bit lines operating as a set are selected, and the two selected bit lines may operate as a sensing bit line pair.

Referring to FIG. 5, at least a portion of the 1-1 sub-memory array SMA11 and at least a portion of the 2-1 sub-memory array SMA21 may overlap the 1-1 local sense amplifier region LSAB11 in a planar manner, and the 1-1 local sense amplifier region LSAB11 may be positioned between the 1-1 sub-memory array SMA11 and the 2-1 sub-memory array SMA21. At least a portion of the 2-1 sub-memory array SMA21 and at least a portion of the 3-1 sub-memory array SMA31 may overlap, along the third direction D3, the 2-1 local sense amplifier region LSAB21, and the 2-1 local sense amplifier region LSAB21 may be disposed between the 3-1 sub-memory array SMA31 and the 2-1 sub-memory array SMA21.

The 1-1 and 2-1 local sense amplifier regions LSAB11, LSB21 may be provided at the boundary between the 1-1 to 3-1 sub-memory arrays SMA11 to SMA31. A local sense amplifier region may only be provided within the first low block group RBG1, and a local sense amplifier region may not be provided between the first low block group RBG1 and the second low block group RBG2. For example, the local sense amplifier region may not be provided between the 3-1 sub-memory array SMA31 and the 4-1 sub-memory arrays SMA41 of the second row block group RBG2. According to an embodiment, some components of the peripheral circuit 100 may be outside the local sense amplifier region between the first low block group RBG1 and the second low block group RBG2.

According to an embodiment, the local sense amplifier circuits included in each of the 1-1 and 2-1 local sense amplifier regions LSAB11, LSAB21 may be electrically connected to a predetermined third number of bit lines. The circuits arranged in the 1-1 local sense amplifier region LSAB11 may operate as one local sense amplifier circuit. The circuits arranged in the 2-1 local sense amplifier region LSAB21 may operate as one local sense amplifier circuit.

The local sense amplifier circuits arranged in each of the 1-1 and 2-1 local sense amplifier regions LSAB11, LSAB21 may be connected to the bit lines of the 1-1 sub-memory array SMA11, the bit lines of the 2-1 sub-memory array SMA21, and the bit lines of the 3-1 sub-memory array SMA31. For example, a local sense amplifier circuit arranged in the 1-1 local sense amplifier region LSAB11 may be connected to a bit line of the 1-1 sub-memory array SMA11, a bit line of the 2-1 sub-memory array SMA21, and a bit line of the 3-1 sub-memory array SMA31.

One bit line sense amplifier included in the local sense amplifier circuit may be electrically connected to a bit line of a corresponding 1-1 sub-memory array SMA11, a bit line of a corresponding 2-1 sub-memory array SMA21, and a bit line of a corresponding 3-1 sub-memory array SMA31. That is, one bit line sense amplifier included in the local sense amplifier circuit may be electrically connected to three bit lines included in different sub-memory arrays.

The local sense amplifier circuit may select sensing bit line pair to be connected to one bit line sense amplifier among three corresponding bit lines. The local sense amplifier circuit may amplify the difference in voltage level sensed in a selected sensing bit line pair among a plurality of sensing bit line pairs and provide it to a global input/output line pair.

In the present disclosure, a ‘local sense amplifier region’ may mean a region where a local sense amplifier circuit is arranged between a plurality of bit lines and a global input/output line pair to select a sensing bit line pair and perform an amplification and transmission operation of a voltage sensed in the sensing bit line pair.

Each of the 1-1 local sense amplifier region LSAB11, the 2-1 local sense amplifier region LSAB21, the 1-1 sub-memory array SMA11, the 2-1 sub-memory array SMA21, and the 3-1 sub-memory array SMA31 may correspond to each of the 1-2 and 1-8 local sense amplifier regions LSAB12 to LSAB18, the 2-2 to 2-8 local sense amplifier regions LSAB22 to LSAB28, the 1-2 to 1-8 sub-memory arrays SMA12 to SMA28, the 2-2 to 2-8 sub-memory arrays SMA22 to SMA28, and the 3-2 to 3-8 sub-memory arrays SMA32 to SMA38. The description of the 1-1 local sense amplifier region LSAB11, the 2-1 local sense amplifier region LSAB21, the 1-1 sub-memory array SMA11, the 2-1 sub-memory array SMA21, and the 3-1 sub-memory array SMA31 described above may be applied to the 1-2 and 1-8 local sense amplifier regions LSAB12 to LSAB18, the 2-2 to 2-8 local sense amplifier regions LSAB22 to LSAB28, the 1-2 to 1-8 sub-memory arrays SMA12 to SMA28, the 2-2 to 2-8 sub-memory arrays SMA22 to SMA28, and the 3-2 to 3-8 sub-memory arrays SMA32 to SMA38.

Referring to FIG. 5, the 1-1 sub memory array SMA11 may be arranged to overlap at least a portion of the 1-1 sub word line driver region SWB11 and at least a portion of the 1-2 sub word line driver region SWB12 in the third direction D3. According to an embodiment, the 1-1 sub-memory array SMA11 may include word lines connected to at least some of the sub word line drivers arranged in the 1-1 sub word line driver region SWB11 and at least some of the sub word line drivers arranged in the 1-2 sub word line driver region SWB12.

The 1-2 sub-memory array SMA12 may be arranged to overlap at least a portion of the 1-2 sub word line driver region SWB12 and at least a portion of the 1-3 sub word line driver region SWB13 in the third direction D3. The 1_3 sub memory array SMA13 may be arranged to overlap at least a portion of the 1-3 sub word line driver region SWB13 and at least a portion of the 1-4 sub word line driver region SWB14 in the third direction D3. The 1_4th sub memory array SMA14 may be arranged to overlap at least a portion of the 1-4 sub word line driver region SWB14 and at least a portion of the 1-5 sub word line driver region SWB15 in the third direction D3. The 1-5 sub-memory array SMA15 may be arranged to overlap at least a portion of the 1-5 sub word line driver region SWB15 and at least a portion of the 1-6 sub word line driver region SWB16 in the third direction D3. The 1-6 sub-memory array SMA16 may be arranged to overlap at least a portion of the 1-6 sub word line driver region SWB16 and at least a portion of the 1-7 sub word line driver region SWB17 in the third direction D3. According to an embodiment, the 1-6 sub-memory array SMA16 may include word lines connected to at least some of the sub word line drivers arranged in the 1-6 sub word line driver region SWB16 and at least some of the sub word line drivers arranged in the 1-7 sub word line driver region SWB17. The 1-7 sub-memory array SMA17 may be arranged to overlap at least a portion of the 1-7 sub word line driver region SWB17 and at least a portion of the 1-8 sub word line driver region SWB18 in the third direction D3. The 1_8th sub memory array SMA18 may be arranged to overlap at least a portion of the 1-8 sub word line driver region SWB18 and at least a portion of the 1-9 sub word line driver region SWB19 in the third direction D3.

The 1-1 to 1-9 sub word line driver regions SWB11 to SWB19 may be arranged on a boundary between the 1-1 to 1-8 sub-memory arrays SMA11 to SMA18 or on one side of the first row block RB1. The 1-1 to 1-9 sub word line driver regions SWB11 to SWB19 may be arranged in the second direction D2.

Similarly, each of the 2-1 to 2-9 sub word line driver regions SWB21 to SWB29 and the 2-1 to 2-8 sub-memory arrays SMA21 to SMA28 may correspond to each of the 1-1 to 1-9 sub word line driver regions SWB11 to SWB19 and the 1-1 to 1-8 sub-memory arrays SMA11 to SMA18. The 2-1 to 2-9 sub word line driver regions SWB21 to SWB29 may be arranged on a boundary between the 2-1 to 2-8 sub-memory arrays SMA21 to SMA28 or on one side of the second row block RB2. The 2-1 to 2-9 sub word line driver regions SWB21 to SWB29 may be arranged in the second direction D2.

Similarly, each of the 3-1 to 3-9 sub word line driver regions SWB31 to SWB39 and the 3-1 to 3-8 sub-memory arrays SMA31 to SMA38 may correspond to each of the 1-1 to 1-9 sub word line driver regions SWB11 to SWB19 and the 1-1 to 1-8 sub-memory arrays SMA11 to SMA18. The 3-1 to 3-9 sub word line driver regions SWB31 to SWB39 may be arranged on a boundary between the 3-1 to 3-8 sub-memory arrays SMA31 to SMA38 or on one side of the third row block RB3. The 3-1 to 3-9 sub word line driver regions SWB31 to SWB39 may be arranged in the second direction D2.

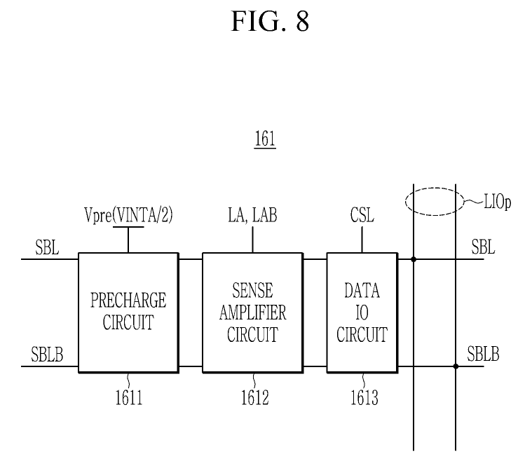

FIG. 6 is an enlarged circuit diagram of area A in FIG. 5. FIG. 7 is a block diagram illustrating a local sense amplifier circuit according to some embodiments. FIG. 8 is a block diagram illustrating a bit line sense amplifier according to some embodiments.

Specifically, FIG. 6 illustrates a planar arrangement of the 1-1 to 3-1 sub-memory arrays SMA11 to SMA31 and the 1-1 and 2-1 local sense amplifier regions LSAB11, LSAB21 of FIG. 5. FIG. 7 illustrates a circuit connection between the 1-1 to 1-3 sub-memory arrays SMA11 to SMA13 of FIG. 6 and the local sense amplifier circuits of the 1-1 and 2-1 local sense amplifier regions LSAB11, LSAB21.

Referring to FIGS. 2, 4 to 8, the 1-1 sub-memory array SMA11 may include a first word line WL1 extending in a second direction D2, 1-a to 1-d bit lines BL1a to BL1d extending in a first direction D1, and a plurality of memory cells MC arranged at points where the first word line WL1 and the 1-a to 1-d bit lines BL1a to BL1d intersect.

The 2-1 sub-memory array SMA21 may include a second word line WL2 extending in a second direction D2, 2-a to 2-d bit lines BL2a to BL2d extending in a first direction D1, and a plurality of memory cells MC arranged at points where the second word line WL2 and the 2-a to 2-d bit lines BL2a to BL2d intersect.

The 3-1 sub-memory array SMA31 may include a third word line WL3 extending in the second direction D2, 3-a to 3-d bit lines BL3a to BL3d extending in the first direction D1, and a plurality of memory cells MC arranged at points where the third word line WL3 and the 3-a to 3-d bit lines BL3a to BL3d intersect. The 1-1 to 3-1 sub-memory arrays SMA11 to SMA31 include one word line, but the number of word lines is only an example and embodiments are not limited thereto.

The 1-a bit line BL1a, the 2-a bit line BL2a, and the 3-a bit line BL3a may be spaced apart from each other in the first direction D1.

Each of the 1-b bit line BL1b, the 2-b bit line BL2b, and the 3-b bit lines BL3b may be arranged adjacent to each of the 1-a bit line BL1a, the 2-a bit line BL2a, and the 3-a bit line BL3a in the second direction D2. The 1-b bit line BL1b, the 2-b bit line BL2b, and the 3-b bit lines BL3b may be spaced apart from each other in the first direction D1.

Each of the 1-c bit line BL1c, the 2-c bit line BL2c, and the 3-c bit line BL3c may be arranged adjacent to each of the 1-b bit line BL1b, the 2-b bit line BL2b, and the 3-b bit lines BL3b in the second direction D2. The 1-c bit line BL1c, the 2-c bit line BL2c, and the 3-c bit line BL3c may correspond to each other and operate as a set, and may be spaced apart from each other in the first direction D1.

Each of the 1-d bit line BL1d, the 2-d bit line BL2d, and the 3-d bit line BL3d may be arranged adjacent to each of the 1-c bit line BL1c, the 2-c bit line BL2c, and the 3-d bit line BL3d in the second direction D2. The 1-d bit line BL1d, the 2-d bit line BL2d, and the 3-d bit line BL3d may be spaced apart from each other in the first direction D1.

The local sense amplifier circuit portion arranged in the 1-1 local sense amplifier region LSAB11 may include an a-th bit line sense amplifier 161a, a c-th bit line sense amplifier 161c, an a-th bit line selection circuit 162a, a c-th bit line selection circuit 162c, and a first local sense amplifier circuit 163_1.

The a-th bit line sense amplifier 161a may be electrically connected to the output terminal of the a-th bit line selection circuit 162a and the third a bit line BL3a. The a-th bit line selection circuit 162a may be electrically connected to the 1-a bit line BL1a and the 2-a bit line BL2a. The a-th bit line selection circuit 162a may select one of the 1-a bit line BL1a and the 2-a bit line BL2a based on the first bit line selection signal BLs1 provided from the first row decoder 140a. The a-th bit line selection circuit 162a may be implemented as a part of a logic circuit within the peripheral circuit 100, but embodiments are not limited thereto, and according to an embodiment, the a-th bit line selection circuit 162a may be implemented as a multiplexer that performs a selection operation based on the first bit line selection signal BLs1.

The 1-a bit line BL1a, the 2-a bit line BL2a, and the 3-a bit line BL3a are electrically connected to The a-th bit line sense amplifier 161a and correspond to each other so that they may operate as a set. The a-th bit line sense amplifier 161a may drive two bit lines among the 1-a bit line BL1a, the 2-a bit line BL2a, and the 3-a bit line BL3a as a sensing bit line pair through the selection operation of the a-th bit line selection circuit 162a.

The 1-a bit line BL1a may be electrically connected to the a-th bit line selection circuit 162a through the 1-a bit line contact CNT1a extending in the third direction D3, and the 1-a bit line contact CNT1a may overlap, along the third direction D3, the 1-1 local sense amplifier region LSAB11. The 2-a bit line BL2a may be electrically connected to the a-th bit line selection circuit 162a through a 2-a bit line contact CNT2a extending in the third direction D3, and the 2-a bit line contact CNT2a may overlap the 1-1 local sense amplifier region LSAB11 along the third direction D3. The 3-a bit line BL3a may be electrically connected to The a-th bit line sense amplifier 161a through a 3-a bit line contact CNT3a extending in the third direction D3, and the 3-a bit line contact CNT3a may not overlap the 1-1 local sense amplifier region LSAB11 along the third direction D3.

The a-th bit line sense amplifier 161a may detect data stored in a memory cell MC by amplifying the voltage difference occurring in a sensing bit line pair. Data sensed by the a-th bit line sense amplifier 161a may be transmitted to the first local data input/output line pair LIOp1. Below, the description of the bit line sense amplifier 161 of FIG. 8 replaces the description of the components of the a-th to d-th bit line sense amplifiers 161a to 161d of FIG. 7.

With additional reference to FIG. 8, the bit line sense amplifier 161 may include a precharge circuit 1611, a sense amplifier circuit 1612, and a data input/output circuit 1613.

The precharge circuit 1611 may precharge the sensing bit line pair SBL, SBLB to the precharge voltage Vpre in response to the precharge control signal. Depending on embodiments, the voltage level of the precharge voltage Vpre may be half the voltage level of the internal power supply voltage VINTA.

According to an embodiment, the precharge circuit 1611 may include a first transistor, a second transistor and a third transistor. The first and second transistors are connected in series between the sensing bit line pair SBL, SBLB and may provide a precharge voltage Vpre to the sensing bit line pair SBL, SBLB based on a precharge control signal. The third transistor is connected between the sensing bit line pair SBL, SBLB and may equalize the voltage level of the sensing bit line pair SBL, SBLB based on the precharge control signal. According to an embodiment, the first to third transistors may be NMOS transistors.

The sense amplifier circuit 1612 may detect data by sensing and amplifying the voltage difference between a sensing bit line pair SBL, SBLB based on a sensing control signal pair LA, LAB. According to an embodiment, the sense amplifier circuit 1612 may include a first sense amplifier circuit and a second sense amplifier circuit, each connected to a sensing bit line pair SBL, SBLB. The above first sense amplifier circuit may be connected in series between the sensing bit line pairs SBL, SBLB, and sense “low” level data on one line of the sensing bit line pairs SBL, SBLB based on a sensing control signal LA and amplify the other line to the level of the internal power supply voltage VINTA. The second sense amplifier circuit may be connected in series between the sensing bit line pairs SBL, SBLB, and sense “high” level data on one line of the sensing bit line pairs SBL, SBLB based on an inverted sensing control signal LAB and amplifiy the other line to a level of ground voltage.

In the sensing operation of the sense amplifier circuit 1612, the sensing control signal LA may be changed from the precharge voltage Vpre to the internal power supply voltage VINTA, and the inverted sensing control signal LAB may be changed from the precharge voltage VCC/2 to the ground voltage.

The data input/output circuit 1613 may transmit data of a sensing bit line pair SBL, SBLB to a local data input/output line pair LIOp or transmit data of a local data input/output line pair LIOp to a sensing bit line pair SBL, SBLB in response to a column select signal CSL. According to an embodiment, the data input/output circuit 1613 may include fourth and fifth transistors. The fourth transistor may electrically connect between a sensing bit line SBL and a local data input/output line based on a column select signal CSL, and the fifth transistor may electrically connect between a complementary sensing bit line SBLB and a local data input/output line based on the column select signal CSL.

Each of the c-th bit line sense amplifiers 161c and the c-th bit line selection circuits 162c may correspond to the a-th bit line sense amplifiers 161a and the a-th bit line selection circuits 162a, respectively.

The c-th bit line sense amplifier 161c may be electrically connected to the output terminal of the c-th bit line selection circuit 162c and the 3-c bit line BL3c. The c-th bit line selection circuit 162c may be electrically connected to the 1-c bit line BL1c and the 2-c bit line BL2c. The c-th bit line selection circuit 162c may select one of the 1-c bit line BL1c and the 2-c bit line BL2c based on the first bit line selection signal BLs1 provided from the first row decoder 140a. The c-th bit line selection circuit 162c may be implemented as a part of a logic circuit within the peripheral circuit 100, but embodiments are not limited thereto, and according to an embodiment, the c-th bit line selection circuit 162c may be implemented as a multiplexer that performs a selection operation based on the first bit line selection signal BLs1.

The first c bit line BL1c, the 2-c bit line BL2c, and the third c bit line BL3c are electrically connected to the c bit line sense amplifier 161c and correspond to each other so that they may operate as a set. The c bit line sense amplifier 161c may drive two bit lines among the 1-c bit line BL1c, the 2-c bit line BL2c, and the 3-c bit line BL3c as a sensing bit line pair through the selection operation of the c-th bit line selection circuit 162c.

The 1-c bit line BL1c may be electrically connected to the c-th bit line selection circuit 162c through a 1-c bit line contact CNT1c extending in the third direction D3, and the 1-c bit line contact CNT1c may overlap the 1-1 local sense amplifier region LSAB11 along the third direction D3. The 2-c bit line BL2c may be electrically connected to the c-th bit line selection circuit 162c through a 2-c bit line contact CNT2c extending in the third direction D3, and the 2-c bit line contact CNT2c may overlap the 1-1 local sense amplifier region LSAB11 along the third direction D3. The 3-c bit line BL3c may be electrically connected to the c bit line sense amplifier 161c through a 3-c bit line contact CNT3c extending in the third direction D3, and the 3-c bit line contact CNT3c may not overlap the 1-1 local sense amplifier region LSAB11 along the third direction D3.

The c-th bit line sense amplifier 161c may detect data stored in a memory cell MC by amplifying the voltage difference occurring in a sensing bit line pair. Data sensed by the c-th bit line sense amplifier 161c may be transmitted to the first local data input/output line pair LIOp1.

The first local sense amplifier circuit 163_1 may be connected to the a-th and c-th bit line sense amplifiers 161a, 161c through the first local input/output line pair LIOp1.

The first local sense amplifier circuit 163_1 may be activated in response to a control signal, and when the first local sense amplifier circuit 163_1 is activated, the voltage difference of the first local input/output line pair LIOp1 may be amplified and provided to the first global input/output line pair GIOp1.

The local sense amplifier circuit portion arranged in the 2-1 local sense amplifier region LSAB21 may include a b-th bit line sense amplifier 161b, a d-th bit line sense amplifier 161d, a b bit line selection circuit 162b, a d-th bit line selection circuit 162d, and a second local sense amplifier circuit 163_2.

The b-th bit line sense amplifier 161b may be electrically connected to the output terminal of the b-th bit line selection circuit 162b and the 1-b bit line BL1b. The b-th bit line selection circuit 162b may be electrically connected to the 2-b bit line BL2b and the 3-b bit line BL3b. The b-th bit line selection circuit 162b may select one of the 2-b bit line BL2b and the 3-b bit lines BL3b based on the second bit line selection signal BLs2 provided from the first row decoder 140a. The b-th bit line selection circuit 162b may be implemented as a part of a logic circuit within the peripheral circuit 100, but embodiments are not limited thereto, and according to an embodiment, The b-th bit line selection circuit 162b may be implemented as a multiplexer that performs a selection operation based on the second bit line selection signal BLs2.

The 1-b bit line BL2b, the 2-b bit line BL2b, and the 3-b bit lines BL3b are electrically connected to the b-th bit line sense amplifier 161b and correspond to each other so that they may operate as a set. The b-th bit line sense amplifier 161b may drive two bit lines among the 1-b bit line BL1b, the 2-b bit line BL2b, and the 3-b bit lines BL3b as a sensing bit line pair through the selection operation of The b-th bit line selection circuit 162b.

The 1-b bit line BL1b may be electrically connected to the 2-b bit line sense amplifier 161b through a 1-b bit line contact CNT1b extending in the third direction D3, and the 1-b bit line contact CNT1b may not overlap the 2-1 local sense amplifier region LSAB21 along the third direction D3. The 2-b bit line BL2b may be electrically connected to the 2-b bit line selection circuit 162b through a 2-b bit line contact CNT2b extending in the third direction D3, and the 2-b bit line contact CNT2b may overlap the 2-1 local sense amplifier region LSAB21 along the third direction D3. The 3-b bit lines BL3b may be electrically connected to The b-th bit line selection circuit 162b through a 3-b bit lines contact CNT3b extending in the third direction D3, and the 3-b bit lines contact CNT3b may overlap the 2-1 local sense amplifier region LSAB21 along the third direction D3.

The b-th bit line sense amplifier 161b may detect data stored in a memory cell MC by amplifying the voltage difference occurring in a sensing bit line pair. Data sensed by The b-th bit line sense amplifier 161b may be transmitted to the second local data input/output line pair LIOp2.

Each of the d-th bit line sense amplifiers 161d and the d-th bit line selection circuits 162d may correspond to The b-th bit line sense amplifiers 161b and The b-th bit line selection circuits 162b, respectively.

The d-th bit line sense amplifier 161d may be electrically connected to the output terminal of the d-th bit line selection circuit 162d and the first d bit line BL1d. The d-th bit line selection circuit 162d may be electrically connected to the 2-d bit line BL2d and the 3-d bit line BL3d. The d-th bit line selection circuit 162d may select one of the 2-d bit line BL2d and the 3-d bit line BL3d based on the second bit line selection signal BLs2 provided from the first row decoder 140a. The d-th bit line selection circuit 162d may be implemented as a part of a logic circuit within the peripheral circuit 100, but embodiments are not limited thereto, and according to an embodiment, the d-th bit line selection circuit 162d may be implemented as a multiplexer that performs a selection operation based on the second bit line selection signal BLs2.

The first d bit line BL1d, the 2-d bit line BL2d, and the 3-d bit line BL3d are electrically connected to the d-th bit line sense amplifier 161d and correspond to each other so that they may operate as a set. The d-th bit line sense amplifier 161d may drive two bit lines among the 1-d bit line BL1d, the 2-d bit line BL2d, and the 3-d bit line BL3d as a sensing bit line pair through the selection operation of the d-th bit line selection circuit 162d.

The 1-d bit line BL1d may be electrically connected to the d-th bit line sense amplifier 161d through a 1-d bit line contact CNT1d extending in the third direction D3, and the 1-d bit line contact CNT1d may not overlap the 2-1 local sense amplifier region LSAB21 along the third direction D3. The 2-d bit line BL2d may be electrically connected to the d-th bit line selection circuit 162d through a 2-d bit line contact CNT2d extending in the third direction D3, and the 2-d bit line contact CNT2d may overlap the 2-1 local sense amplifier region LSAB21 along the third direction D3. The 3-d bit line BL3d may be electrically connected to the d-th bit line selection circuit 162d through a 3-d bit line contact CNT3d extending in the third direction D3, and the 3-d bit line contact CNT3d may overlap the 2-1 local sense amplifier region LSAB21 along the third direction D3.

The d-th bit line sense amplifier 161d may detect data stored in a memory cell MC by amplifying the voltage difference occurring in a sensing bit line pair. Data sensed by the d-th bit line sense amplifier 161d may be transmitted to the second local data input/output line pair LIOp2.

The second local sense amplifier circuit 163_2 may be connected to the b-th and d-th bit line sense amplifiers 161b, 161d through the second local input/output line pair LIOp2.

The second local sense amplifier circuit 163_2 may be activated in response to a control signal, and when the second local sense amplifier circuit 163_2 is activated, the voltage difference of the second local input/output line pair LIOp2 may be amplified and provided to the first global input/output line pair GIOp1.

According to an embodiment, at least some of the plurality of bit line contacts may be arranged, in a planar view, in an ‘L’ shape on the first local sense amplifier region LSAB11. Taking FIG. 6 as an example, the 2-a bit line contact CNT2a, the 1-a bit line contact CNT1a, and the 1-b bit line contact CNT1b may be arranged in an ‘L’ shape on the 1-1 local sense amplifier region LSAB11. Similarly, the 2-c bit line contact CNT2c, the 1-c bit line contact CNT1c, and the 1-d bit line contact CNT1d may be arranged in an ‘L’ shape on the 1-1 local sense amplifier region LSAB11.

According to an embodiment, at least some of the plurality of bit line contacts may be arranged, in a planar view, in an ‘L’ shape on the 2-1 local sense amplifier region LSAB21. Taking FIG. 6 as an example, the 2-b bit line contact CNT2b, the 3-b bit line contact CNT3b, and the 3-a bit line contact CNT3a may be arranged in an ‘L’ shape on the 2-1 local sense amplifier region LSAB21. Similarly, the 2-b bit line contact CNT2b, the 3-b bit line contact CNT3b, and the 3-a bit line contact CNT3a may be arranged in an ‘L’ shape on the 2-1 local sense amplifier region LSAB21.

In a memory device 10 according to an embodiment, three 1-1 to 1-3 sub-memory arrays SMA11 to SMA31 arranged in a first direction D1 may operate as a single set through a bit line selection circuit and a bit line sense amplifier structure arranged in a 1-1 local sense amplifier region LSAB11 and a 2-1 local sense amplifier region LSAB21. In a memory device 10 according to an embodiment, the number of bit line sense amplifiers for driving three 1-1 to 1-3 sub-memory arrays SMA11 to SMA31 may be reduced and the area of the peripheral circuit 100 may be reduced through a bit line selection circuit and a bit line sense amplifier structure. Additionally, in the memory device 10 according to the embodiment, a local sense amplifier region may not be provided on one side of a low block group.

In FIGS. 6 and 7, a local sense amplifier circuit is described which is arranged in a local sense amplifier region between the 1-1 sub-memory array SMA11, the 2-1 sub-memory array SMA21, and the 3-1 sub-memory array SMA31 and the 1-1 to 3-1 sub-memory arrays SMA11 to SMA31. However, the description of FIGS. 6 and 7 may be applied to three sub-memory arrays arranged in the first direction in the same row block group and to a local sense amplifier circuit which is arranged in a local sense amplifier region between the three sub-memory arrays.

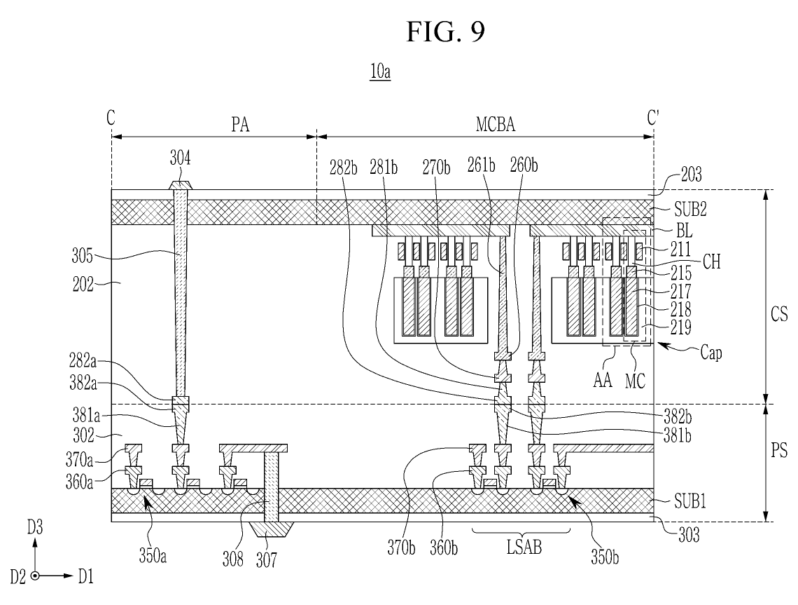

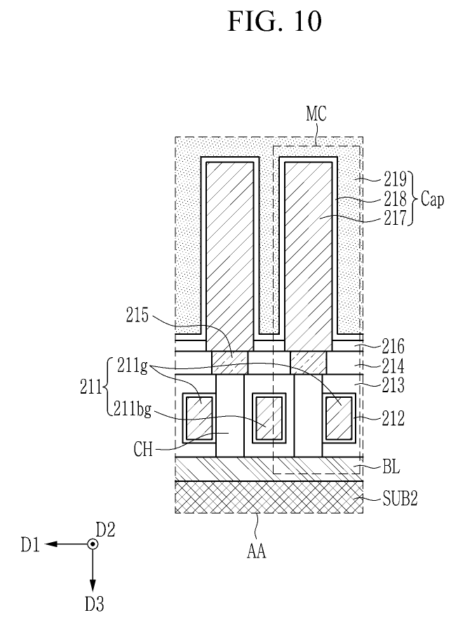

FIG. 9 is a cross-sectional view taken along lines C to C’ of an example memory device of FIG. 4. FIG. 10 is an enlarged view of area AA in FIG. 9.

Referring to FIGS. 2, 3 to 6, 9 and 10, a memory device 10a according to some embodiments may have a C2C (chip to chip) structure, which is a COP structure. The C2C structure may mean fabricating an upper chip including a memory cell area CS on a first wafer, fabricating a lower chip including a peripheral circuit area PS on a second wafer different from the first wafer, and then connecting the upper chip and the lower chip to each other by a bonding method. For example, the above bonding method may mean a method of electrically connecting a bonding metal disposed on the top metal layer of an upper chip and a bonding metal disposed on the top metal layer of a lower chip. For example, if the bonding metal is arranged as copper(Cu), the bonding method may be a Cu-Cu bonding method, and the bonding metal may be aluminum or tungsten.

Each of the peripheral circuit area PS and the memory cell area CS of the semiconductor memory device 10a according to the embodiment may include an external pad bonding area PA and a memory cell bonding area MCBA.

The peripheral circuit area PS may include a first substrate SUB1, a first interlayer insulating layer 302, a plurality of circuit elements 350a, 350b arranged on the first substrate SUB1, a first metal layer 360a, 360b connected to each of the plurality of circuit elements 350a, 350b, and a second metal layer 370a, 370b arranged on the first metal layer 360a, 360b. In some embodiments, the first metal layer 360a, 360b may be formed of relatively high resistivity tungsten, and the second metal layer 370a, 370b may be formed of relatively low resistivity copper.

In the present disclosure, only the first metal layer 360a, 360b and the second metal layer 370a, 370b are illustrated, but this is not limited to the first metal layer, and at least one more metal layer may be arranged on the second metal layer 370a, 370b. At least a portion of one or more metal layers disposed on top of the second metal layer 370a, 370b may be aluminum having lower resistance than copper on which the second metal layer 370a, 370b is disposed.

The first interlayer insulating layer 302 is disposed on the first substrate SUB1 to cover a plurality of circuit elements 350a, 350b, the first metal layer 360a, 360b, and the second metal layer 370a, 370b, and may include an insulating material such as silicon oxide, silicon nitride, or the like.

A memory cell area CS may provide the plurality of memory cells MC. The memory cell area CS may include a second substrate SUB2, a bit line BL, and a first metal layer 260b connected to each of the bit lines BL through a bit line contact 261b, and a second metal layer 270b disposed on the first metal layer 260b. In an embodiment, the first metal layer 260b may be tungsten, which has relatively high resistance, and the second metal layer 270b may be copper, which has relatively low resistance. Through a plurality of memory cells MC, bit lines BL, and bit line contacts 261b, each may correspond to a memory cell MC, a bit line BL, and a bit line contact in FIGS. 2 to 8.

In an embodiment illustrated in FIG. 9, an area where a plurality of memory cells MC and bit lines BL are arranged may be defined as a memory cell bonding area MCBA. Referring to FIGS. 9 and 10, a memory cell area CS in a memory cell bonding area MCBA may include a bit line BL, a memory vertical channel layer CH, a plurality of first gate electrodes 211, a first gate insulating layer 212, and a capacitor structure Cap.

According to an embodiment, the plurality of memory cells MC may include vertical channel transistors (VCT). The vertical channel transistor may refer to a structure in which a memory vertical channel layer CH extends along a third direction D3 that is vertical from a second substrate SUB2. The third direction D3 proceeds perpendicularly to the first direction D1 in which the bit line BL extends and the second direction D2 in which the first gate electrode 211 extends.

The bit line BL may be arranged to extend parallel to the lower surface of the second substrate SUB2. In some embodiments, three or more bit lines BL may be spaced apart in the first direction D1 within the memory cell area CS, and an insulating pattern may be arranged in spaces between the plurality of bit lines BL. The above insulating pattern may extend in the first direction D1, and the upper surface of the insulating pattern may be arranged at the same height as the upper surface of the bit line BL.

For example, the bit line BL may include doped polysilicon, a metal, a conductive metal nitride, a conductive metal silicide, a conductive metal oxide, or a combination thereof. For example, the bit line BL may be made of, but is not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof. The bit line BL may comprise a single layer or the plurality of layers of the aforementioned materials. In some embodiments, the bit line BL may include a two-dimensional semiconductor material, for example, the two-dimensional semiconductor material may include graphene, carbon nanotubes, or a combination thereof.

The memory vertical channel layers CH may be spaced apart from each other in a first direction D1 on the bit line BL. The memory vertical channel layers CH may be arranged in a matrix form spaced apart from each other in the first direction D1 and the second direction D2 on a plurality of bit lines. A bottom portion of the memory vertical channel layer CH functions as a first source/drain region, an upper portion of the memory vertical channel layer CH functions as a second source/drain region, and a portion of the memory vertical channel layer CH between the first and second source/drain regions may function as a channel region.

For example, the memory vertical channel layer CH may include silicon, an oxide semiconductor, or a combination thereof, and for example, the oxide semiconductor may include InxGayZnzO IGZO, InxGaySizO, InxSnyZnzO, InxZnyO, ZnxO, ZnxSnyO, ZnxOyN, ZrxZnySnzO, SnxO, HfxInyZnzO, GaxZnySnzO, AlxZnySnzO, YbxGayZnzO, InxGayO, or a combination thereof. The memory vertical channel layer CH may include a single layer or the plurality of layers of the oxide semiconductor. In some examples, the memory vertical channel layer CH may have a bandgap energy greater than the bandgap energy of silicon. For example, the memory vertical channel layer CH may have a bandgap energy of about 1.5 eV to 5.6 eV. For example, a memory vertical channel layer CH may have optimal channel performance when it has a bandgap energy of about 2.0 eV to 4.0 eV. For example, the memory vertical channel layer CH may be, but is not limited to, polycrystalline or amorphous. In embodiments, the memory vertical channel layer CH may include a two-dimensional semiconductor material, for example, the two-dimensional semiconductor material may include graphene, carbon nanotubes, or a combination thereof.

The first gate electrode 211 may extend in the second direction D2 on both sidewalls of the memory vertical channel layer CH. The first gate electrode 211 may include a first sub-gate electrode 211gfacing a first sidewall of the memory vertical channel layer CH and a first back gate electrode 211bg facing a second sidewall opposite to the first sidewall of the memory vertical channel layer CH. The first sub-gate electrode 211g may function as any one of the plurality of word lines WL of FIGS. 2 to 8, and the first back gate electrode 211bg may perform the function of forming a ground potential of a vertical channel transistor including a memory vertical channel layer CH.

The first gate electrode 211 may include doped polysilicon, a metal, a conductive metal nitride, a conductive metal silicide, a conductive metal oxide, or a combination thereof. For example, the first gate electrode 211 may be formed of, but is not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof.

The first gate insulating layer 212 may be arranged to surround the first gate electrode 211, and at least a portion of the first gate insulating layer 212 may be arranged between the first gate electrode 211 and the memory vertical channel layer CH. In FIG. 10, the first gate insulating layer 212 is arranged in a form that surrounds the first gate electrode 211, but according to an embodiment, the first gate insulating layer 212 may have a form that is arranged along at least a portion of a sidewall of the first gate insulating layer 212.

In embodiments, the first gate insulating layer 212 may be formed of a silicon oxide film, a silicon oxynitride film, a high-k film having a higher dielectric constant than the silicon oxide film, or a combination thereof. The above high-k dielectric film may be made of a metal oxide or a metal oxide nitride. For example, a high-k dielectric film that may be used as the first gate insulating layer 212 may be formed of, but is not limited to, HfO2, HfSiO, HfSiON, HfTaO, HfTiO, HfZrO, ZrO2, Al2O3, or a combination thereof.

A first interlayer insulating film 213 may be provided in the space between the first gate electrode 211 on the bit line BL and the memory vertical channel layer CH. In FIG. 10, the first interlayer insulating film 213 is illustrated as one continuous material layer, but depending on the embodiment, the first interlayer insulating film 213 may be arranged as a plurality of insulating patterns.

A capacitor contact 215 may be provided on the memory vertical channel layer CH. The capacitor contact 215 may be arranged to vertically overlap the memory vertical channel layer CH in the third direction D3. The capacitor contact 215 may be formed of, but is not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof. The first upper insulating layer 214 may surround the sidewall of the capacitor contact 215 on the first interlayer insulating film 213.

A first etching stop film 216 may be provided on the first upper insulating layer 214, and a capacitor structure Cap may be provided on the first etching stop film 216. The capacitor structure Cap may include a lower electrode 217, a capacitor dielectric layer 218, and an upper electrode 219.

The lower electrode 217 may penetrate the first etching stop film 216 and be electrically connected to the upper surface of the capacitor contact 215. The lower electrode 217 may be arranged in a pillar type extending in the third direction D3, but embodiments are not limited thereto. In embodiments, the lower electrode 217 may be arranged to overlap the capacitor contact 215 along the third direction D3. Alternatively, a landing pad may be further arranged between the capacitor contact 215 and the lower electrode 217, so that the lower electrode 217 may be arranged in a hexagonal shape.

The first gate electrode 211, the memory vertical channel layer CH, and the capacitor structure Cap may function as one memory cell MC. The first gate electrode 211 and the memory vertical channel layer CH may function as a transistor, and the capacitor structure Cap may function as a capacitor. The memory cell MC may correspond to any one of the plurality of memory cells MC of FIGS. 2 to 8.

In the memory cell bonding area MCBA, a plurality of memory cells MC may be electrically connected to the first metal layer 260b and the second metal layer 270b through bit line contacts 261b extending in the third direction D3.

A lower bonding metal 381b, 382b may be provided on the second metal layer 370b of the memory cell bonding area MCBA. In the memory cell bonding area MCBA, the lower bonding metal 381b, 382b of the peripheral circuit area PS may be electrically connected to the upper bonding metal 281b, 282b of the memory cell area CS by a bonding method, and the lower bonding metal 381b, 382b and the upper bonding metal 281b, 282b may be aluminum, copper, or tungsten.

In the memory cell bonding area MCBA, the bit line BL may be electrically connected to circuit elements 350b that provide components arranged in the local sense amplifier region LSAB of the peripheral circuit area PS. For example, a bit line BL may be connected to an upper bonding metal 281b, 282b through a bit line contact 261b in a memory cell area CS, and the upper bonding metal 281b, 282b may be connected to a lower bonding metal 381b, 382b that is connected to circuit elements 350b arranged in a local sense amplifier region LSAB. Components arranged in the local sense amplifier region LSAB may overlap a plurality of memory cells MC and bit lines BL along the third direction D3. The local sense amplifier region LSAB may correspond to the 1-1 and 2-8 local sense amplifier regions LSAB11 to LSAB28.

The external pad bonding area PA may include a first external pad 307 positioned on a peripheral circuit area PS and a second external pad 304 positioned on a memory cell area CS. Referring to FIG. 9, a lower insulating film 303 covering a lower surface of the first substrate SUB1 may be provided on the lower portion of the first substrate SUB1, and a first external pad 307 may be provided on the lower insulating film 303. The first external pad 307 is electrically connected to at least one of a plurality of circuit elements 350a, 350b arranged in the peripheral circuit area PS through the first external contact plug 308, and may be separated from the first substrate SUB1 by the lower insulating film 303. A side insulating film may be arranged between the first external contact plug 308 and the first substrate SUB1 to electrically isolate the first external contact plug 308 and the first substrate SUB1.

An upper insulating film 203 covering the upper surface of the second substrate SUB2 may be provided on the upper substrate SUB2, and a second external pad 304 may be provided on the upper insulating film 203. The second external pad 304 may be electrically connected to at least one of a plurality of circuit elements 350a, 350b arranged in the peripheral circuit area PS through a second external contact plug 305 extending in the third direction D3 and penetrating the second interlayer insulating layer 202 of the memory cell area CS. The second external pad 304 may be separated from the second substrate SUB2 by the upper insulating film 203. The second external contact plug 305 is connected to the upper bonding metal 282a, and the upper bonding metal 282a may be connected in a bonding manner to the lower bonding metal 381a, 382a connected to the circuit elements 350a of the peripheral circuit area PS. The lower bonding metal 381a, 382a and the upper bonding metal 282a may be made of aluminum, copper, or tungsten.

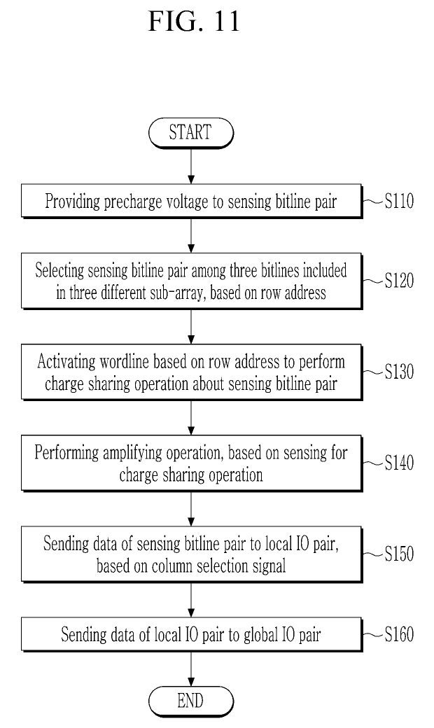

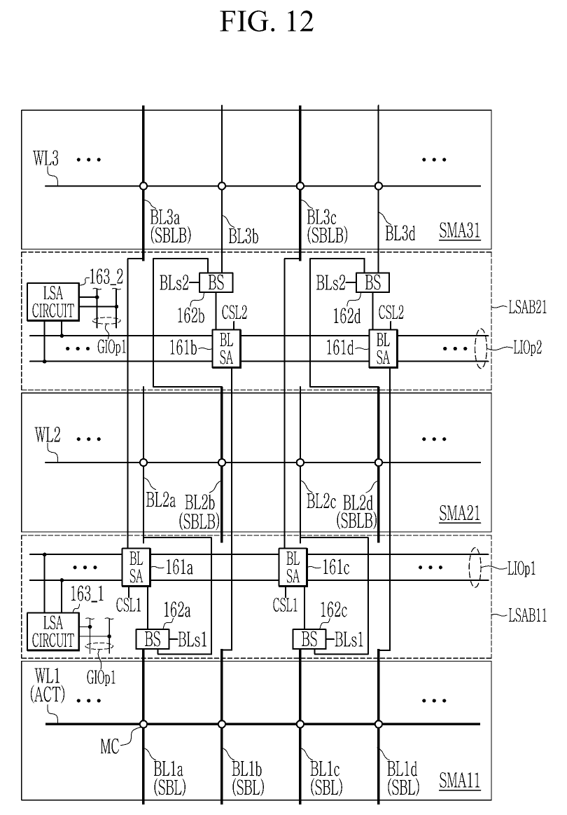

FIG. 11 is a flowchart illustrating a method of operating a memory device according to some embodiments. FIGS. 12 to 14 are drawings for explaining a method of operating a memory device according to some embodiments. Specifically, each of FIGS. 12 to 14 illustrates an example of a selection operation for a sensing bit line pair in a local sense amplifier circuit according to activation of a word line.

Referring to FIGS. 7 to 8 and 11, the bit line sense amplifier 161 provides a precharge voltage Vpre to the sensing bit line pair SBL, SBLB(S110).

Taking FIG. 7 as an example, The bit line sense amplifiers 161a to 161d may provide a precharge voltage Vpre to the output terminals of the bit line selection circuits 162a to 162d corresponding to the sensing bit line pairs SBL, SBLB and to one bit line (BL3a, BL1b, BL3c, BL1d). Taking The a-th bit line sense amplifier 161a as an example, the a-th bit line sense amplifier 161a may provide a precharge voltage Vpre to the output terminal of the a-th bit line selection circuit 162a and the 3-a bit line BL3a.

The bit line selection circuit selects a sensing bit line pair SBL, SBLB for the bit line sense amplifier 161 among three bit lines included in three different sub-memory arrays based on the row address RA(S120).

Taking FIG. 7 as an example, a-th to d-th bit line selection circuit 162a to 162d receives bit line selection signals BLs1, BLs2 based on a row address RA, and selects one of two connected bit lines to select a sensing bit line pair SBL, SBLB for a bit line sense amplifier 162a to 162d.

The a-th bit line selection circuit 162a may select one of the 1-a and 1-b bit lines BL1a, BL2a based on the first bit line selection signal BLs1. The a-th bit line selection circuit 162a may select one of the 1-a and 1-b bit lines BL1a, BL2a based on the first bit line selection signal BLs1. The b-th bit line selection circuit 162b may select one of the 2-b and 3-b bit lines BL2b, BL3b based on the second bit line selection signal BLs2. The c-th bit line selection circuit 162c may select one of the 1-c and 2-c bit line BL1c, BL2c based on the first bit line selection signal BLs1. The d-th bit line selection circuit 162d may select one of the 2-d and 3-d bit lines BL2d, BL3d based on the second bit line selection signal BLs2.

As an example of FIG. 12, the first row decoder 140a may receive a row address RA for the first word line WL1 of the 1-1 sub-memory array SMA11 and output a bit line selection signal BLs1, BLs2 for the first word line WL1. The a-th bit line selection circuit 162a selects the 1-a bit line BL1a based on the first bit line selection signal BLs1, so that the 1-a bit line BL1a and the 3-a bit line BL3a may be selected as a sensing bit line pair SBL, SBLB for the a-th bit line sense amplifier 161a. The b-th bit line selection circuit 162b selects the 2-b bit line BL2b based on the second bit line selection signal BLs2, so that the 1-b bit line BL1b and the 2-b bit line BL2b may be selected as a sensing bit line pair SBL, SBLB for the b-th bit line sense amplifier 161b. The c-th bit line selection circuit 162c selects the 1-c bit line BL1c based on the first bit line selection signal BLs1, so that the 1-c bit line BL1c and the 3-c bit line BL3c may be selected as the sensing bit line pair SBL, SBLB for the c-th bit line sense amplifier 161c. The d-th bit line selection circuit 162d selects the 2-d bit line BL2d based on the second bit line selection signal BLs2, so that 1-d bit line BL1d and the 2-d bit line BL2d may be selected as a sensing bit line pair SBL, SBLB for the d-th bit line sense amplifier 161d. However, the technical idea of the present disclosure is not limited to the example of the selection operation of the bit line selection circuits 162a to 162d, and according to an embodiment, the b-th bit line selection circuit 162b may select the 3-b bit lines BL3b based on the second bit line selection signal BLs2, or the d-th bit line selection circuit 162d may select the 3-d bit line BL3d based on the second bit line selection signal BLs2.

When the first row decoder 140a receives a row address RA for the first word line WL1 directly connected to the b-th bit line sense amplifier 161b and the d-th bit line sense amplifier 161d, the second bit line selection signal BLs2 provided to the b-th and d-th bit line selection circuits 162b, 162d may be maintained. The b-th and d-th bit line selection circuits 162b, 162d may maintain the selection operation of the bit line based on the second bit line selection signal BLs2 that is maintained.

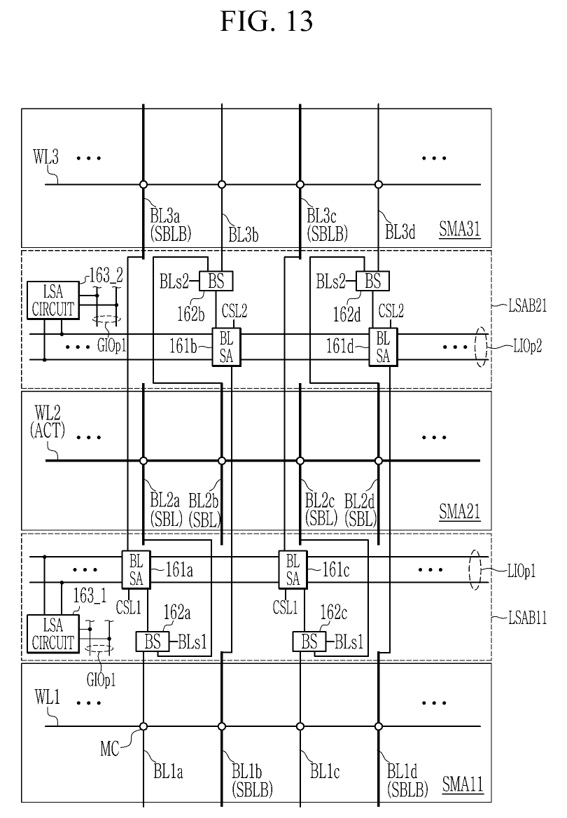

As an example of FIG. 13, the first row decoder 140a may receive a row address RA for the second word line WL2 of the 2-1 sub-memory array SMA21 and output a bit line selection signal BLs1, BLs2 for the second word line WL2. The a-th bit line selection circuit 162a selects the 2-a bit line BL2a based on the first bit line selection signal BLs1, so that the 2-a bit line BL2a and the 3-a bit line BL3a may be selected as the sensing bit line pair SBL, SBLB for the a-th bit line sense amplifier 161a. The b-th bit line selection circuit 162b selects the 2-b bit line BL2b based on the second bit line selection signal BLs2, so that the 2-b bit line BL2b and the 1-b bit line BL1b may be selected as a sensing bit line pair SBL, SBLB for the b-th bit line sense amplifier 161b. The c-th bit line selection circuit 162c selects the 2-c bit line BL2c based on the first bit line selection signal BLs1, so that the 2-c bit line BL2c and the 3-c bit line BL3c may be selected as the sensing bit line pair SBL, SBLB for the c-th bit line sense amplifier 161c. The d-th bit line selection circuit 162d selects the 2-d bit line BL2d based on the second bit line selection signal BLs2, so that the 2-d bit line BL2d and 1-d bit line BL1d may be selected as a sensing bit line pair SBL, SBLB for the d-th bit line sense amplifier 161d.

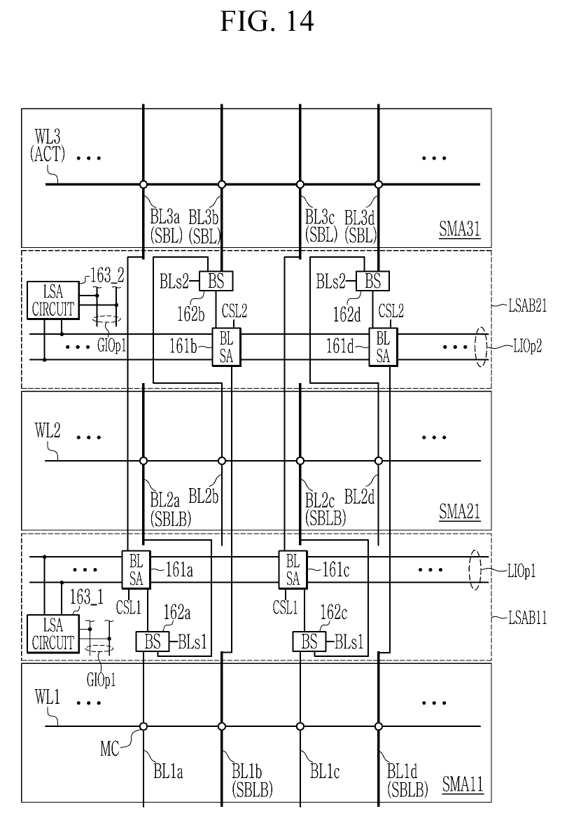

As an example of FIG. 14, the first row decoder 140a may receive a row address RA for the third word line WL3 of the 3-1 sub-memory array SMA31 and output a bit line selection signal BLs1, BLs2 for the third word line WL3. The a-th bit line selection circuit 162a selects the 2-a bit line BL2a based on the first bit line selection signal BLs1, so that the 3-a bit line BL3a and the 2-a bit line BL2a may be selected as the sensing bit line pair SBL, SBLB for the a-th bit line sense amplifier 161a. The b-th bit line selection circuit 162b selects the 3-b bit lines BL3b based on the second bit line selection signal BLs2, so that the 3-b bit lines BL3b and the 1-b bit line BL1b may be selected as a sensing bit line pair SBL, SBLB for the b-th bit line sense amplifier 161b. The c-th bit line selection circuit 162c selects the 2-c bit line BL2c based on the first bit line selection signal BLs1, so that the 3-c bit line BL3c and the 2-c bit line BL2c may be selected as the sensing bit line pair SBL, SBLB for the c-th bit line sense amplifier 161c. The d-th bit line selection circuit 162d selects the 3-d bit line BL3d based on the second bit line selection signal BLs2, so that the 3-d bit line BL3d and 1-d bit line BL1d may be selected as a sensing bit line pair SBL, SBLB for the d-th bit line sense amplifier 161d. However, the technical idea of the present disclosure is not limited to the example of the selection operation of the bit line selection circuits 162a to 162d, and according to an embodiment, the a-th bit line selection circuit 162a may select the 1-a bit line BL1a based on the first bit line selection signal BLs1, or the c-th bit line selection circuit 162c may select the 1-c bit line BL1c based on the first bit line selection signal BLs1.

When the first row decoder 140a receives a row address RA for the third word line WL3 directly connected to the a-th bit line sense amplifier 161a and the c-th bit line sense amplifier 161c, the second bit line selection signal BLs2 provided to the a-th and c-th bit line selection circuits 162a, 162c may be maintained. The a-th and c-th bit line selection circuits 162a, 162c may maintain the selection operation of the bit line based on the first bit line selection signal BLs1 that is maintained.

Referring to FIGS. 13 and 14 as examples, when the first row decoder 140a receives a row address RA for the second word line WL2 and sequentially receives a row address RA for the third word line WL3, the first row decoder 140a may maintain and output the first bit line selection signal BLs1. The a-th and c-th bit line selection circuits 162a, 162c may maintain a bit line selection operation based on the first bit line selection signal BLs1 that is maintained. By maintaining the bit line selection operation of the a-th and c-th bit line selection circuits 162a, 162c, the memory device 10 according to the embodiment may improve the power efficiency of the sensing operation.

The row decoder activates a word line based on a row address RA and performs a charge sharing operation for a sensing bit line pair SBL, SBLB(S130).

The first row decoder 140a may receive a row address RA and activate a word line corresponding to the row address RA. Upon activation of the word line, a charge sharing operation between the memory cell connected to the sensing bit line SBL and the sensing bit line SBL may be performed.

Taking FIG. 12 as an example, the first row decoder 140a may receive a row address RA for the first word line WL1 of the 1-1 sub memory array SMA11 and activate the first word line WL1. According to the activation of the first word line WL1, the 1-a to 1-d bit lines BL1a to BL1d may operate as sensing bit lines SBL, and a charge sharing operation may be performed between the 1-a to 1-d bit lines BL1a to BL1d and the memory cells MC connected to the 1-a to 1-d bit lines BL1a to BL1d.

Taking FIG. 13 as an example, the first row decoder 140a may receive a row address RA for the second word line WL2 of the 2-1 sub memory array SMA21 and activate the second word line WL2. According to the activation of the second word line WL2, the 2-a to 2-d bit lines BL2a to BL2d may operate as sensing bit lines SBL, and a charge sharing operation may be performed between the 2-a to 2-d bit lines BL2a to BL2d and the memory cells MC connected to the 2-a to 2-d bit lines BL2a to BL2d.

Taking FIG. 14 as an example, the first row decoder 140a may receive a row address RA for the third word line WL3 of the 3-1 sub memory array SMA31 and activate the third word line WL3. According to the activation of the third word line WL3, the 3-a to 3-d bit lines BL3a to BL3d may operate as sensing bit lines SBL, and a charge sharing operation may be performed between the 3-a to 3-d bit lines BL3a to BL3d and the memory cells MC connected to the 3-a to 3-d bit lines BL3a to BL3d.

Although steps120 is depicted in the drawing as preceding step s130, in some embodiments, step s130 may precede step s120 or steps s120 and S130 may be performed together.

The bit line sense amplifier 161 performs an amplification operation based on sensing of a charge sharing operation(S140).

The bit line sense amplifier 161 may sense and amplify the voltage difference between the sensing bit line pair SBL, SBLB that occurs based on the charge sharing operation in step s140. The bit line sense amplifier 161 may detect data of a sensing bit line pair SBL, SBLB based on the above amplification operation.

For example, when the data of a memory cell connected to a sensing bit line SBL is ‘1’, The bit line sense amplifier 161 may detect the “high” level data of the sensing bit line SBL and amplify the voltage level of the complementary sensing bit line SBLB to a low voltage, that is, a ground voltage, and detect the “low” level data of the complementary sensing bit line SBLB and amplify the voltage level of the sensing bit line SBL to a high voltage, that is, an internal power supply voltage VINTA.

For example, when data of a memory cell connected to a sensing bit line SBL is ‘0’, The bit line sense amplifier 161 may detect “low” level data of the sensing bit line SBL and amplify the voltage level of the complementary sensing bit line SBLB to a high voltage internal power supply voltage VINTA, and detect “high” level data of the complementary sensing bit line SBLB and amplify the voltage level of the sensing bit line SBL to a low voltage ground voltage.

The bit line sense amplifier 161 transmits data of a sensing bit line pair SBL, SBLB to a local data input/output line pair LIOp based on a column selection signal(S150).

One of the a-th and c-th bit line sense amplifiers 161a, 161c may be activated based on the first column select signal CSL1 to transmit data of a sensing bit line pair detected by the bit line sense amplifier to the first local data input/output line pair LIOp1.

One of the b-th and d-th bit line sense amplifiers 161b, 161d may be activated based on the second column select signal CSL2 to transmit data of a sensing bit line pair detected by the bit line sense amplifier to a second local data input/output line pair LIOp2.

The local sense amplifier circuit transfers data from the local input/output line pair LIOp to the global input/output line pair GIOp(S160).

The first local sense amplifier circuit 163_1 may be activated in response to a control signal, and when the first local sense amplifier circuit 163_1 is activated, the voltage difference of the first local input/output line pair LIOp1 may be amplified and provided to the first global input/output line pair GIOp1.

The second local sense amplifier circuit 163_2 may be activated in response to a control signal, and when the second local sense amplifier circuit 163_2 is activated, the voltage difference of the first local input/output line pair LIOp1 may be amplified and provided to the first global input/output line pair GIOp1.

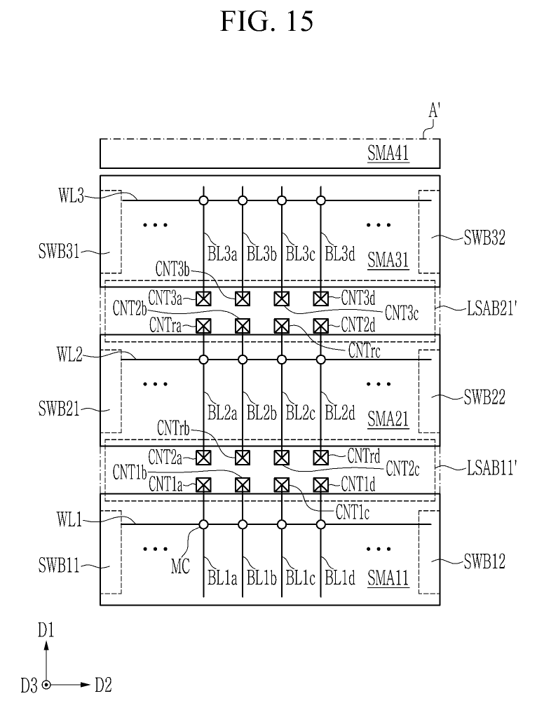

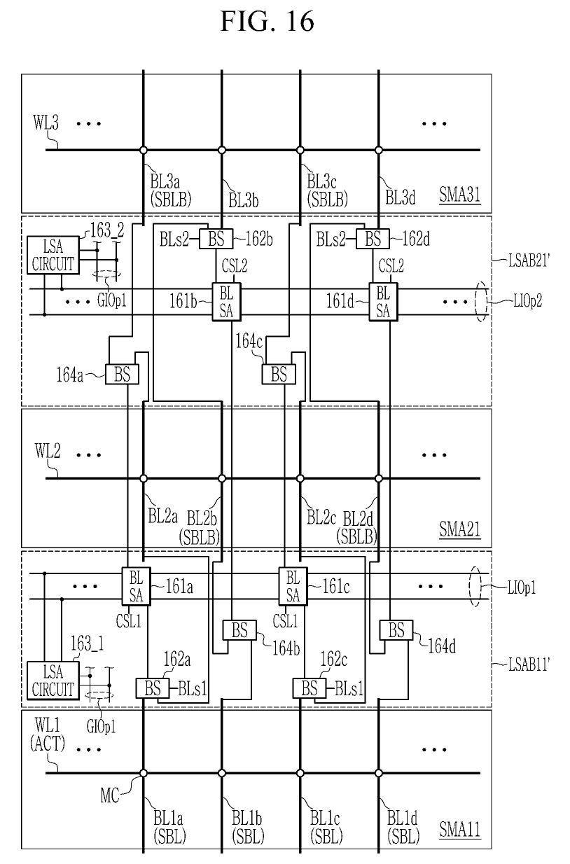

FIGS. 15 and 16 are drawings illustrating memory devices according to some embodiments.

The 1-1 and 2-1 local sense amplifier regions LSAB11’, LSAB21’ of FIGS. 15 and 16 may respectively correspond to the 1-1 and 2-1 local sense amplifier regions LSAB11, LSAB21 of FIGS. 6 and 7. For ease of explanation below, the 1-1 and 2-1 local sense amplifier regions LSAB11’, LSAB21’ will be described with a focus on differences from the 1-1 and 2-1 local sense amplifier regions LSAB11, LSAB21 of FIGS. 6 and 7.

Referring to FIGS. 15 and 16, the local sense amplifier circuit portion arranged in the 1-1 local sense amplifier region LSAB11’ may further include a b-th replica bit line selection circuit 164b and a d-th replica bit line selection circuit 164d. The local sense amplifier circuit arranged in the 2-1 local sense amplifier region LSAB21’ may further include an a-th replica bit line selection circuit 164a and a c-th replica bit line selection circuit 164c.

The b-th bit line sense amplifier 161b arranged in the 2-1 local sense amplifier region LSAB21’ may be electrically connected to the output terminal of The b-th bit line selection circuit 162b and the output terminal of the b-th replica bit line selection circuit 164b. The b-th replica bit line selection circuit 164b may be electrically connected to the 1-b bit line BL1b and the 2-b bit line BL2b.

The b-th replica bit line selection circuit 164b may maintain the connection between the 1-b bit line BL1b and the b-th bit line sense amplifier 161b regardless of the bit line selection signal.

The 1-b bit line BL1b may be electrically connected to the b-th replica bit line selection circuit 164b through a 1-b bit line contact CNT1b extending in the third direction D3. The 1-b bit line contact CNT1b may overlap the 1-1 local sense amplifier region LSAB11’ along the third direction D3, and may not overlap the 2-1 local sense amplifier region LSAB21’ along the third direction D3.

The second b bit line BL2b may be electrically connected to the b-th replica bit line selection circuit 164b through a b-th replica bit line contact CNTrb extending in the third direction D3. The b replica bit line contact CNTrb may overlap the 1-1 local sense amplifier region LSAB11’ along the third direction D3, and may not overlap the 2-1 local sense amplifier region LSAB21’ along the third direction D3.

The d-th bit line sense amplifier 161d arranged in the 2-1 local sense amplifier region LSAB21’ may be electrically connected to the output terminal of the d-th bit line selection circuit 162d and the output terminal of the d-th replica bit line selection circuit 164d. The d-th replica bit line selection circuit 164d may be electrically connected to the 1-d bit line BL1d and the 2-d bit line BL2d.

The d-th replica bit line selection circuit 164d may maintain the connection between the 1-d bit line BL1d and the d-th bit line sense amplifier 161d regardless of the bit line selection signal.

The 1-d bit line BL1d may be electrically connected to the d-th replica bit line selection circuit 164d through a 1-d bit line contact CNT1d extending in the third direction D3. The 1-d bit line contact CNT1d may overlap the 1-1 local sense amplifier region LSAB11’ along the third direction D3, and may not overlap the 2-1 local sense amplifier region LSAB21’ along the third direction D3.

The 2-d bit line BL2d may be electrically connected to the d-th replica bit line selection circuit 164d through a d-th replica bit line contact CNTrd extending in the third direction D3. The d replica bit line contact CNTrd may overlap the 1-1 local sense amplifier region LSAB11’ along the third direction D3, and may not overlap the 2-1 local sense amplifier region LSAB21’ along the third direction D3.

The a-th bit line sense amplifier 161a arranged in the 1-1 local sense amplifier region LSAB11’ may be electrically connected to the output terminal of the a-th bit line selection circuit 162a and the output terminal of the a-th replica bit line selection circuit 164a. The a-th replica bit line selection circuit 164a may be electrically connected to the 2-a bit line BL2a and the 3-a bit line BL3a.

The a-th replica bit line selection circuit 164a may maintain the connection between the 3-a bit line BL3a and the a-th bit line sense amplifier 161a regardless of the bit line selection signal.

The 3-a bit line BL3a may be electrically connected to the a-th replica bit line selection circuit 164a through a 3-a bit line contact CNT3a extending in the third direction D3. The 3-a bit line contact CNT3a may overlap the 2-1 local sense amplifier region LSAB21’ along the third direction D3, and may not overlap the 1-1 local sense amplifier region LSAB11’ along the third direction D3.

The 2-a bit line BL2a may be electrically connected to the a-th replica bit line selection circuit 164a through the a replica bit line contact CNTra extending in the third direction D3. The a-th replica bit line contact CNTra may overlap the 2-1 local sense amplifier region LSAB21’ along the third direction D3, and may not overlap the 1-1 local sense amplifier region LSAB11’ along the third direction D3.

The c bit line sense amplifier 161c arranged in the 1-1 local sense amplifier region LSAB11’ may be electrically connected to the output terminal of the c-th bit line selection circuit 162c and the output terminal of the c-th replica bit line selection circuit 164c. The c-th replica bit line selection circuit 164c may be electrically connected to the 2-c bit line BL2c and the 3-c bit line BL3c.

The c-th replica bit line selection circuit 164c may maintain the connection between the 3rd c bit line BL3c and the c bit line sense amplifier 161c regardless of the bit line selection signal.

The 3-c bit line BL3c may be electrically connected to the c-th replica bit line selection circuit 164c through a 3-c bit line contact CNT3c extending in the third direction D3. The 3-c bit line contact CNT3c may overlap the 2-1 local sense amplifier region LSAB21’ along the third direction D3, and may not overlap the 1-1 local sense amplifier region LSAB11’ along the third direction D3.

The 2-c bit line BL2c may be electrically connected to the c-th replica bit line selection circuit 164c through a c-th replica bit line contact CNTrc extending in the third direction D3. The c-th replica bit line contact CNTrc may overlap the 2-1 local sense amplifier region LSAB21’ along the third direction D3, and may not overlap the 1-1 local sense amplifier region LSAB11’ along the third direction D3.

According to an embodiment, at least some of the plurality of bit line contacts may be arranged, in a plane view, in two columns on the 1-1 local sense amplifier region LSAB11’. Each column may extend in the second direction D2. Taking FIG. 15 as an example, the 1-a to 1-d bit line contacts CNT1a to CNT1d may be extend in a row in the second direction D2 on the first local sense amplifier region LSAB11’. Similarly, the 2-a bit line contact CNT2a, the b-th replica bit line contact CNTrb, the 2-c bit line contact CNT2c, and the d-th replica bit line contact CNTrd may extend in a row in the second direction D2 on the 1-1 local sense amplifier region LSAB11’.

According to an embodiment, at least some of the plurality of bit line contacts may be arranged, when viewed in plane, in two rows on the 2-1 local sense amplifier region LSAB21’. Each column may extend in the second direction D2. Taking FIG. 15 as an example, the 3-a to 3-d bit line contacts CNT3a to CNT3d may be arranged in a row in a planar manner in the second direction D2 on the 2-1 local sense amplifier region LSAB21’. Similarly, the a-th replica bit-line contact CNTra, the 2-th b-th bit-line contact CNT2b, the c-th replica bit line contact CNTrc, and the 2-th d-th bit-line contact CNT2d may be arranged in a row in the second direction D2 on the 2-1 local sense amplifier region LSAB21’.

In a memory device according to an embodiment, three 1-1 to 3-1 sub-memory arrays SMA11 to SMA31 arranged in a first direction D1 may operate as a single set through a bit line selection circuit and a bit line sense amplifier structure arranged in a 1-1 local sense amplifier region LSAB11’ and a 2-1 local sense amplifier region LSAB21’. In a memory device according to an embodiment, the number of bit line sense amplifiers for driving three 1-1 to 1-3 sub-memory arrays SMA11 to SMA31 may be reduced and the area of a peripheral circuit 100 may be reduced through a bit line selection circuit and a bit line sense amplifier structure. Additionally, in a memory device according to an embodiment, a local sense amplifier region may not be provided on one side of a low block group.

A memory device according to an embodiment may easily and simultaneously control differential signals for a sensing bit line pair connected to a bit line sense amplifier through the arrangement of a replica bit line selection circuit corresponding to a bit line selection circuit in a local sense amplifier region, and may improve the operational reliability of The bit line sense amplifier.

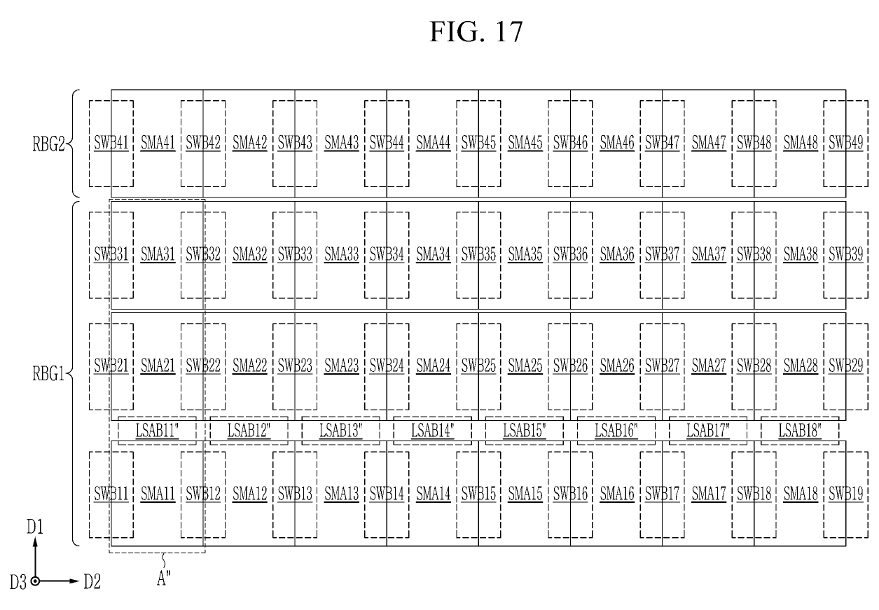

FIGS. 17 to 19 are drawings illustrating memory devices according to some embodiments.

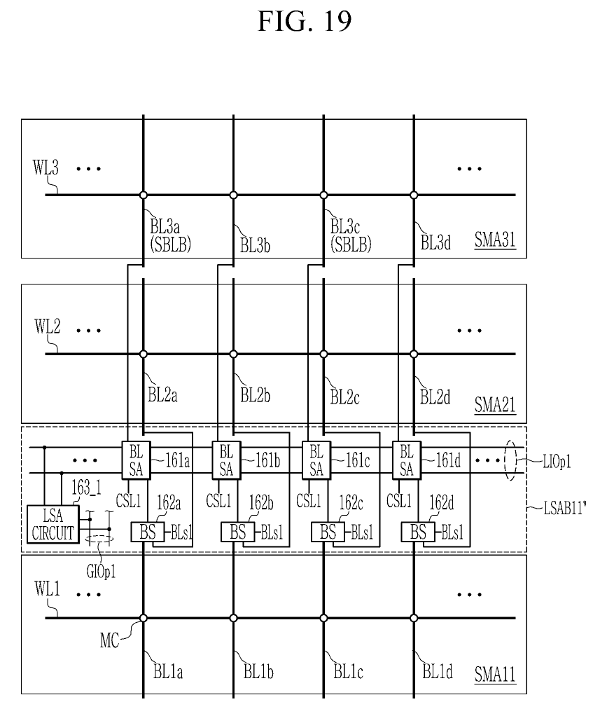

The 1-1 local sense amplifier region LSAB11’’ of FIGS. 17 and 19 may correspond to the 1-1 local sense amplifier region LSAB11 of FIGS. 6 and 7. For ease of explanation below, the 1-1 local sense amplifier region LSAB11’’ will be described focusing on the differences from the 1-1 local sense amplifier region LSAB11 of FIGS. 6 and 7.

Referring to FIGS. 17 to 19, a local sense amplifier region may not be provided between the 2-1 sub-memory array SMA21 and the 3-1 sub-memory array SMA31 in a planar manner. Similarly, a local sense amplifier region may be disposed between the 2-2 to 2-8 sub-memory arrays SMA22 to SMA28 and the 3-2 to 3-8 sub-memory arrays SMA32 to SMA38 when viewed in plane.

The local sense amplifier circuit portion arranged in the 1-1 local sense amplifier region LSAB11’’ may further include a b bit line sense amplifier 161b, a d-th bit line sense amplifier 161d, a b-th bit line selection circuit 162b, and a d-th bit line selection circuit 162d.

Each of the b-th bit line sense amplifier 161b and the b-th bit line selection circuit 162b may correspond to the a-th bit line sense amplifier 161a and the a-th bit line selection circuit 162a, respectively, and each of the d-th bit line sense amplifier 161b and the d-th bit line selection circuit 162d may correspond to the a-th bit line sense amplifier 161a and the a-th bit line selection circuit 162a, respectively.

The b-th bit line sense amplifier 161b may be electrically connected to the output terminal of The b-th bit line selection circuit 162b and the 3-b bit lines BL3b. The b-th bit line selection circuit 162b may be electrically connected to the 1-b bit line BL1b and the 2-b bit line BL2b. The b-th bit line selection circuit 162b may select one of the 1-b bit line BL1b and the 2-b bit line BL2b based on the first bit line selection signal BLs1 provided from the first row decoder 140a.

The 1-b bit line BL1b may be electrically connected to The b-th bit line selection circuit 162b through a 1-b bit line contact CNT1b extending in the third direction D3, and the 1-b bit line contact CNT1b may overlap the 1-1 local sense amplifier region LSAB11’’ along the third direction D3. The 2-b bit line BL2b may be electrically connected to the 2-b bit line selection circuit 162b through a 2-b bit line contact CNT2b extending in the third direction D3, and the 2-b bit line contact CNT2b may overlap the 1-1 local sense amplifier region LSAB11’’ along the third direction D3. The 3-b bit lines BL3b may be electrically connected to the 3-b bit lines sense amplifier 161b through a 3-b bit lines contact CNT3b extending in the third direction D3, and the 3-b bit lines contact CNT3b may not overlap the 1-1 local sense amplifier region LSAB11’’ along the third direction D3.

The b-th bit line sense amplifier 161b may detect data stored in a memory cell MC by amplifying the voltage difference occurring in a sensing bit line pair. Data sensed by The b-th bit line sense amplifier 161b may be transmitted to the first local data input/output line pair LIOp1.

The d-th bit line sense amplifier 161d may be electrically connected to the output terminal of the d-th bit line selection circuit 162d and the 3-d bit line BL3d. The d-th bit line selection circuit 162d may be electrically connected to the 1-d bit line BL1d and the 2-d bit line BL2d. The d-th bit line selection circuit 162d may select one of the first d bit line BL1d and the 2-d bit line BL2d based on the first bit line selection signal BLs1 provided from the first row decoder 140a.

The 1-d bit line BL1d may be electrically connected to the d-th bit line selection circuit 162d through a 1-d bit line contact CNT1d extending in the third direction D3, and the 1-d bit line contact CNT1d may overlap the 1-1 local sense amplifier region LSAB11’’ along the third direction D3. The 2-d bit line BL2d may be electrically connected to the d-th bit line selection circuit 162d through a 2-d bit line contact CNT2d extending in the third direction D3, and the 2-d bit line contact CNT2d may overlap the 1-1 local sense amplifier region LSAB11’’ along the third direction D3. The 3-d bit line BL3d may be electrically connected to the d-th bit line sense amplifier 161d through a 3-d bit line contact CNT3d extending in the third direction D3, and the 3-d bit line contact CNT3d may not overlap the 1-1 local sense amplifier region LSAB11’’ along the third direction D3.

The b-th bit line sense amplifier 161b may detect data stored in a memory cell MC by amplifying the voltage difference occurring in a sensing bit line pair. Data sensed by The b-th bit line sense amplifier 161b may be transmitted to the first local data input/output line pair LIOp1.

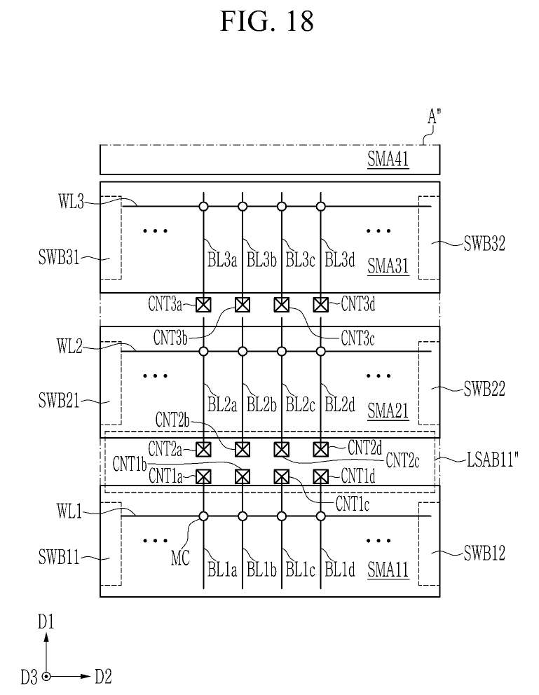

According to an embodiment, at least some of the plurality of bit line contacts may be arranged, when viewed in plane, in two columns on the 1-1 local sense amplifier region LSAB11’’. Each column may extend in the second direction D2. Taking FIG. 18 as an example, the 1-a to 1-d bit line contacts CNT1a to CNT1d may be extend in a row in the second direction D2 on the first local sense amplifier region LSAB11’’. Similarly, the 2-a to 2-d bit line contacts CNT2a to CNT2d may be arranged in a row in a planar manner in the second direction D2 on the 1-1 local sense amplifier region LSAB11’’.

According to an embodiment, at least some of the plurality of bit line contacts may extend in one column between the 2-1 sub-memory array SMA21 and the 3-1 sub-memory array SMA31. The above one column may be extended in the second direction D2. Taking FIG. 18 as an example, the 3-a to 3-d bit line contacts CNT3a to CNT3d may be arranged in a row in the second direction D2 between the 2-1 sub-memory array SMA21 and the 3-1 sub-memory array SMA31.

In a memory device according to an embodiment, three 1-1 to 1-3 sub-memory arrays SMA11 to SMA31 arranged in a first direction D1 may operate as a set through a bit line selection circuit and a bit line sense amplifier structure arranged in the 1-1 local sense amplifier region LSAB11’’. In a memory device according to an embodiment, the number of bit line sense amplifiers for driving three 1-1 to 1-3 sub-memory arrays SMA11 to SMA31 may be reduced and the area of a peripheral circuit 100 may be reduced through a bit line selection circuit and a bit line sense amplifier structure. Additionally, in a memory device according to an embodiment, a local sense amplifier region may not be on one side of a low block group.

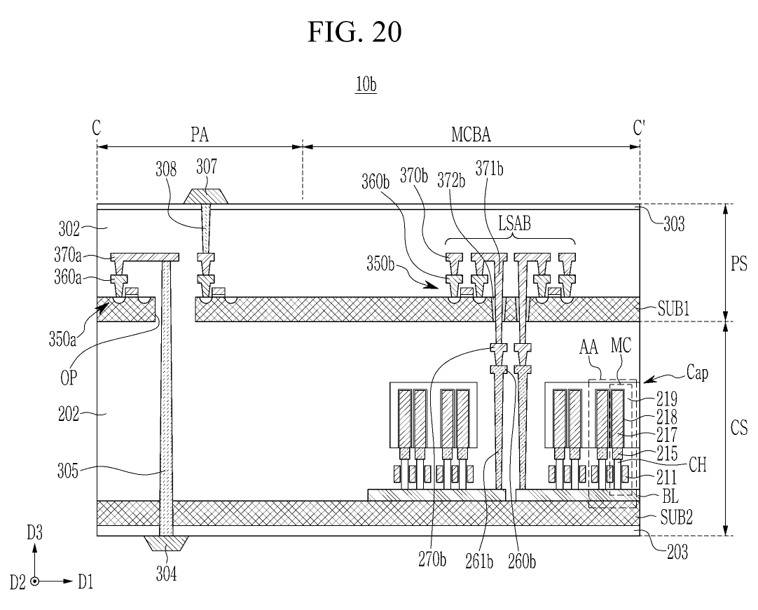

FIG. 20 is a cross-sectional view taken along line C-C’ of an example of the memory device of FIG. 3. The memory device 10b of FIG. 20 may correspond to the memory device 10a of FIG. 8. For ease of explanation below, the memory device 10b will be described focusing on the differences from the memory device 10a of FIG. 8.

Referring to FIG. 20, a memory device 10b according to some embodiments may have a POC structure, in which a peripheral circuit area PS may be provided above a memory cell area CS in the third direction D3.

Compared to the memory device 10a of FIG. 9, the lower bonding metals (381a, 382a, 381b, 382b) and the upper bonding metals 282a, 281b, 282b are not arranged in the memory device 10b.

Additionally, a first substrate SUB1 may be provided between the second metal layer 370a, 370b of the peripheral circuit area PS and the second metal layer 270b of the memory cell area CS in the memory device 10b. Accordingly, a plurality of circuit elements 350a, 350b of the peripheral circuit area PS may be arranged above the second metal layer 270b of the memory cell area CS with respect to the third direction D3. A lower insulating film 303 covering a plurality of circuit elements 350a, 350b of a peripheral circuit area PS and a first interlayer insulating layer 302 may be provided on the upper portion of the first substrate SUB1.

According to an embodiment, the first substrate SUB1 may define an opening OP in the outer pad bonding area PA. According to an embodiment, the first interlayer insulating layer 302 and the second interlayer insulating layer 202 may be in contact through the opening OP. The second external contact plug 305 extends along the third direction D3 through the opening OP and penetrates the second interlayer insulating layer 202 and a portion of the first interlayer insulating layer 302 to be electrically connected to the second metal layer 370a of the external pad bonding area PA. According to an embodiment, the second external contact plug 305 may be electrically connected to circuit elements 350a within the external pad bonding area PA.

According to an embodiment, a through via 371b extending along the third direction D3 in the memory cell bonding area MCBA and penetrating through a portion of the first and second interlayer insulating layers 202, 302 and the first substrate SUB1 may be arranged. A side insulating film 372b may be interposed between the first substrate SUB1 and the through via 371b.

In the memory cell bonding area MCBA, the through via 371b may extend in the third direction D3 to contact and electrically connect the second metal layer 270b of the memory cell area CS and the second metal layer 370b of the peripheral circuit area PS. Circuit elements 350b included in the local sense amplifier region LSAB and a plurality of bit line contacts 261b may be electrically connected through through vias 371b.

The through via 371b may include a challenging material. For example, the conductive material may be any one of a doped semiconductor material (doped silicon, doped germanium, etc.), a conductive metal nitride (titanium nitride, tantalum nitride, etc.), a metal (tungsten, titanium, tantalum, etc.), and a metal-semiconductor compound (tungsten silicide, cobalt silicide, titanium silicide, etc.).

The side insulating film 372b may be selected from the group including a silicon oxide film, a silicon nitride film, a silicon oxynitride film, a carbon-containing silicon oxide film, a carbon-containing silicon nitride film, and a carbon-containing silicon oxynitride film.

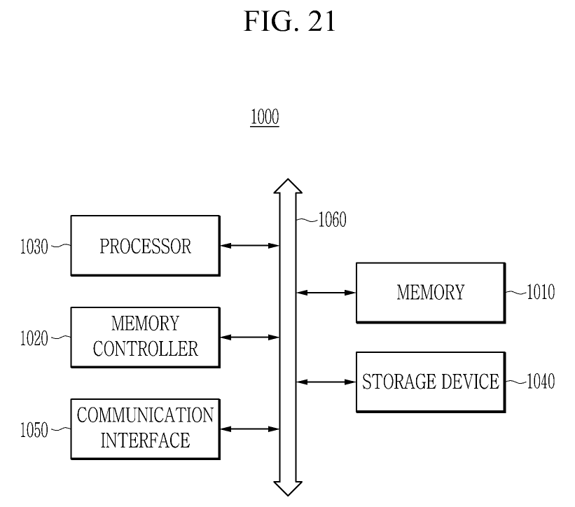

FIG. 21 is a block diagram illustrating a computer device according to some embodiments.

Referring to FIG. 21, a computing device 1000 includes a processor 1030, a memory 1010, a memory controller 1020, a storage device 1040, a communication interface 1050, and a bus 1060. The computing device 1000 may further include other general-purpose components.

The processor 1030 controls the overall operation of each component of the computing device 1000. The processor 1030 may be implemented as at least one of various processing units such as a central processing unit (CPU), an application processor (AP), and a graphic processing unit (GPU).

Memory 1010 stores various data and commands. The memory 1010 may be implemented as a memory device described with reference to FIGS. 1 to 20. According to an embodiment, the memory 1010 may be a three-dimensional volatile memory device of a COP structure or a POC structure. The memory 1010 may be a memory device in which three sub-memory arrays arranged sequentially in one direction operate as a set to reduce the number of bit line sense amplifiers and improve area efficiency.

The memory controller 1020 may control input/output of data or commands in the memory 1010. In an embodiment, the memory controller 1020 may be provided as a separate chip from the processor 1030. In an embodiment, the memory controller 1020 may be provided as an internal component of the processor 1030.

The storage device 1040 non-volatilely stores programs and data. In some embodiments, the storage device 1040 may be implemented as non-volatile memory. The communication interface 1050 supports wired and wireless Internet communication of the computing device 1000. Additionally, the communication interface 1050 may support various communication methods other than Internet communication. The bus 1060 provides communication capabilities between components of the computing device 1000. The bus 1060 may include at least one type of bus depending on the communication protocol between the components.

While aspects of embodiments have been particularly shown and described, it will be understood that various changes in form and details may be made therein without departing from the spirit and scope of the following claims.

What is claimed is:

1. A memory device comprising:
a first sub-memory array, a second sub-memory array and a third sub-memory array arranged sequentially along a first direction;
a first bit line selection circuit connected to a first bit line in the first sub-memory array and a second bit line in the second sub-memory array, wherein the first bit line and the second bit line extend along the first direction; and
a first bit line sense amplifier connected to an output terminal of the first bit line selection circuit and a third bit line in the third sub-memory array and extending along the first direction.

2. The memory device of claim 1, wherein the first bit line selection circuit is configured to receive a bit line selection signal based on a row address and select one of the first bit line and the second bit line based on the bit line selection signal.

3. The memory device of claim 2, wherein the first sub-memory array comprises a first word line extending along a second direction intersecting the first direction, and
wherein the first bit line selection circuit is configured to select the first bit line in response to the first word line being activated.

4. The memory device of claim 3, wherein the second sub-memory array comprises a second word line extending along the second direction, and
wherein the first bit line selection circuit is configured to select the second bit line in response to the second word line being activated.

5. The memory device of claim 2, wherein the third sub-memory array comprises a word line extending along a second direction intersecting the first direction, and
wherein the first bit line selection circuit maintains selection of the one of the first bit line and the second bit line in response to the word line being activated.

6. The memory device of claim 1, wherein the second bit line is spaced apart from the first bit line along the first direction, and
wherein the third bit line is spaced apart from the second bit line along the first direction.

7. The memory device of claim 1, wherein a local sense amplifier circuit of the memory device comprises the first bit line selection circuit and the first bit line sense amplifier, and
wherein the local sense amplifier circuit is between the first sub-memory array and the second sub-memory array.

8. The memory device of claim 7, wherein at least a portion of the local sense amplifier circuit overlaps the first sub-memory array along a third direction perpendicular to each of the first direction and a second direction intersecting the first direction.

9. The memory device of claim 8, further comprising a substrate on which the first sub-memory array, the second sub-memory array and the third sub-memory array are arranged,
wherein the first bit line is connected to the first bit line selection circuit through a bit line contact extending along the third direction, and
wherein the bit line contact overlaps the local sense amplifier circuit along the third direction.

10. The memory device of claim 1, further comprising a replica bit line selection circuit connected to the second bit line and the third bit line,
wherein the first bit line sense amplifier is connected to the third bit line through the replica bit line selection circuit.

11. The memory device of claim 10, wherein the replica bit line selection circuit is configured to maintain a connection between the third bit line and the first bit line sense amplifier.

12. The memory device of claim 1, further comprising:
a second bit line selection circuit connected to a fourth bit line in the first sub-memory array and adjacent to the first bit line along a second direction intersecting the first direction, and a fifth bit line in the second sub-memory array and adjacent to the second bit line along the second direction; and
a second bit line sense amplifier connected to an output terminal of the second bit line selection circuit, and a sixth bit line in the third sub-memory array and adjacent to the third bit line along the second direction.

13. A memory device comprising:
a memory cell area comprising a first sub-memory array, a second sub-memory array and a third sub-memory array arranged sequentially along a first direction; and
a first local sense amplifier circuit between the first sub-memory array and the second sub-memory array,
wherein the first local sense amplifier circuit at least partially overlaps the first sub-memory array and the second sub-memory array along a third direction, and
wherein the first local sense amplifier circuit is connected to a first bit line in the first sub-memory array that extends along the first direction, a second bit line in the second sub-memory array that extends along the first direction, and a third bit line in the third sub-memory array that extends along the first direction.

14. The memory device of claim 13, wherein the first local sense amplifier circuit comprises:
a first bit line selection circuit connected to the first bit line and the second bit line; and
a first bit line sense amplifier connected to an output terminal of the first bit line selection circuit and the third bit line.

15. The memory device of claim 13, wherein the memory cell area further comprises a substrate on which the first sub-memory array to the third sub-memory array are arranged,
wherein the first bit line is connected to the first local sense amplifier circuit through a bit line contact extending along the third direction, and
wherein the bit line contact overlaps the first local sense amplifier circuit along the third direction.

16. The memory device of claim 13, further comprising a second local sense amplifier circuit between the second sub-memory array and the third sub-memory array, wherein the second local sense amplifier circuit at least partially overlaps the second sub-memory array and the third sub-memory array along the third direction, and the second local sense amplifier circuit is connected to a fourth bit line in the first sub-memory array adjacent to the first bit line along a second direction intersecting the first direction, a fifth bit line in the second sub-memory array adjacent to the second bit line along the second direction, and a sixth bit line in the third sub-memory array adjacent to the third bit line along the second direction.

17. The memory device of claim 16, wherein
the memory cell area comprises a fourth sub-memory array adjacent the third sub-memory array along the first direction, and
wherein a local sense amplifier circuit is not provided between the third sub-memory array and the fourth sub-memory array.

18. A method of operating a memory device comprising:
selecting a sensing bit line pair from among a first bit line, a second bit line and a third bit line respectively arranged in a first sub-memory array, a second sub-memory array and a third sub-memory array that are sequentially arranged along a first direction;
activating a word line in any one of the first sub-memory array to the third sub-memory array based on a row address, to perform a charge sharing operation between the sensing bit line pair and a memory cell connected to the word line;
detecting data of the sensing bit line pair based on the charge sharing operation; and
transmitting data of the sensing bit line pair to a local input/output line pair based on a column selection signal.

19. The method of operating the memory device of claim 18, wherein the selecting the sensing bit line pair comprises receiving a bit line selection signal from a bit line selection circuit and connecting one of the first bit line and the second bit line to a bit line sense amplifier based on the bit line selection signal.

20. The method of operating the memory device of claim 19, wherein the bit line selection circuit and the bit line sense amplifier are between the first sub-memory array and the second sub-memory array.
